(19) United States
(12) Patent Application Publication
(10) Pub. No.: US 2016/0075922 A1
(43) Pub. Date: Mar. 17, 2016

(54) TEMPORARY ADHESIVE FOR PRODUCTION OF SEMICONDUCTOR DEVICE, AND ADHESIVE SUPPORT AND PRODUCTION METHOD OF SEMICONDUCTOR DEVICE USING THE SAME

(71) Applicant: FUJIFILM Corporation, Tokyo (JP)

(72) Inventors: Yu IWAI, Haibara-gun (JP); Kazuhiro FUJIMAKI, Haibara-gun (JP); Ichiro KOYAMA, Haibara-gun (JP); Atsushi NAKAMURA, Haibara-gun (JP)

(73) Assignee: FUJIFILM Corporation, Tokyo (JP)

(21) Appl. No.: 14/953,697

(22) Filed: Nov. 30, 2015

Related U.S. Application Data
(62) Division of application No. 14/743,619, filed on Jun. 18, 2015.
Application No. 14/743,619 is a continuation of application No. PCT/JP2013/084442, filed on Dec. 24, 2013.

(30) Foreign Application Priority Data
Dec. 27, 2012 (JP) 2012-286366

(51) Int. Cl. C09J 151/00; H01L 21/683

(52) U.S. Cl. CPC C09J 151/003; H01L 21/6835; H01L 2221/68327

(57) ABSTRACT

By a temporary adhesive for production of semiconductor device containing (A) a radical polymerizable monomer or oligomer containing a fluorine atom or a silicon atom, (B) a polymer compound, and (C) a radical polymerization initiator, a temporary adhesive for production of semiconductor device, which is excellent in coating property, which reduces a problem of generation of gas therefrom in the temporary support even under high temperature condition when the member to be processed (for example, a semiconductor wafer) is subjected to a mechanical or chemical processing, and further which can easily release the temporary support for the member processed without imparting damage to the member processed even after being subjected to a process at a high temperature, and an adhesive support and a production method of semiconductor device using the same are provided.

### CROSS REFERENCE TO RELATED APPLICATION

This is a continuation of International Application No. PCT/JP2013/084442 filed on Dec. 24, 2013, and claims priority from Japanese Patent Application No. 2012-286366 filed on Dec. 27, 2012, the entire disclosures of which are incorporated herein by reference.

### TECHNICAL FIELD

The present invention relates to a temporary adhesive for production of semiconductor device, and an adhesive support and a production method of semiconductor device using the same.

### BACKGROUND ART

Heretofore, in the production process of semiconductor device, for example, IC or LSI, ordinarily, a large number of IC chips are formed on a semiconductor silicon wafer and diced by dicing.

With the needs for further miniaturization and higher performance of electronic devices, further miniaturization and higher integration of IC chip mounted on the electronic device are requested, however, the high integration of the integrated circuit in the plane direction of a silicon substrate is close to the limit.

As an electrical connection method from an integrated circuit in an IC chip to an external terminal of the IC chip, a wire bonding method has been heretofore widely known. In order to reduce the size of the IC chip, in recent years, a method where a through hole is provided in a silicon substrate and a metal plug, as the external terminal is connected to the integrated circuit so as to pass through the through hole (method of forming a so-called through-silicon electrode (TSV)) is known. However, according to the method of forming a through silicon-electrode alone, the needs of higher integration for IC chip in recent years as described above are not sufficiently fulfilled.

In the light of the above, a technique of improving the integration density per unit area of the silicon substrate by making the integrated circuit in IC chip multi-layered is known. However, since the multi-layered integrated circuit increases the thickness of the IC chip, reduction in the thickness of members constituting the IC chip is required. As to the reduction in the thickness of the member, for example, reduction in the thickness of the silicon substrate has been studied and is promising not only to lead to the miniaturization of IC chip but also to save labor in a through-hole producing step of the silicon substrate in the production of through-silicon electrode.

As a semiconductor silicon wafer used in a production process of semiconductor device, the semiconductor silicon wafer having a thickness from about 700 to about 900 μm is widely known. In recent years, for the purpose of miniaturization of IC chip, it has been attempted to reduce the thickness of semiconductor silicon wafer to 200 μm or less.

However, since the semiconductor silicon wafer having the thickness of 200 μm or less is very thin and thus, a member for producing semiconductor device using the semiconductor silicon wafer as a base material is also very thin, and in the case where the member is subjected to further processing or where the member is simply moved, it is difficult to support the member stably and without imparting damage to the member.

In order to solve the problem described above, a technique is known wherein a semiconductor wafer having a device provided on the surface thereof before thinning and a supporting substrate for processing are temporarily adhered with a silicone adhesive, a back surface of the semiconductor wafer is ground to make it thin, the semiconductor wafer is punched to provide a through-silicon electrode, and then the supporting substrate for processing is released from the semiconductor wafer (see Patent Document 1). It is described that according to the technique, resistance to grinding at the grind of back surface of the semiconductor wafer, heat resistance in an anisotropic dry etching step or the like, chemical resistance at plating and etching, smooth final release from the supporting substrate for processing and a low adherend contamination property are able to be achieved at the same time.

Also, as a method of supporting a wafer, a technique is known which is a method for supporting a wafer by a support layer system, wherein between the wafer and the support layer system, a plasma polymer layer obtained by a plasma deposition method is interposed as a separation layer, and an adhesive strength between the support layer system and the separation layer is made larger than an adhesive strength between the wafer and the separation layer so as to be easily released the wafer from the separation layer when the wafer is released from the support layer system (see Patent Document 2).

Also, a technique of performing temporary adhesion using a polyethersulfone and a viscosity imparting agent, and then releasing the temporary adhesion with heating is known (see Patent Document 3).

Also, a technique of performing temporary adhesion with a mixture composed of a carboxylic acid and an amine, and then releasing the temporary adhesion with heating is known (see Patent Document 4).

Also, a technique is known wherein a device wafer and a supporting substrate are bonded with pressure to be adhered in a state where an adhesion layer composed of a cellulose polymer and the like is heated, and then the device wafer is released from the supporting substrate by laterally sliding under heating (see Patent Document 5).

Also, an adhesion film composed of syndiotactic 1,2-polybutadiene and a photopolymerization initiator, an adhesive force of which is changed by irradiation of radiation is known (see Patent Document 6).

Further, a technique is known wherein a supporting substrate and a semiconductor wafer are temporary adhered with an adhesive composed of a polycarbonate, the semiconductor wafer is subjected to processing, and by irradiating active energy ray and then heating, the semiconductor wafer processed is released from the supporting substrate (see Patent Document 7).

Also, an adhesive tape which is composed of an adhesive layer formed from an adhesive composition comprising an energy radiation curable copolymer having an energy radiation polymerizable unsaturated group in its side chain, an epoxy resin, and a thermally active latent epoxy resin curing agent and an adhesive force of which is changed by irradiation of radiation is known (see Patent Document 8).

Also, a composition for adhesive agent layer containing a fluorine compound, and a monomer and/or an oligomer, which can be used for adhering a semiconductor chip and a device is known (see Patent Document 9).

Also, a resin composition containing a silicone macromonomer, which can be used for a reattachable adhesive sheet is known (see Patent Document 10).

Also, an adhesive composition containing a thermoplastic resin, a radical polymerizable compound, a radical generator, and a silicone monomer is known (see Patent Document 11).

### PRIOR ART DOCUMENT

### Patent Document

Patent Document 1: JP-A-2011-119427 (the term “JP-A” as used herein means an “unexamined published Japanese patent application”)

Patent Document 2: JP-T-2009-528688 (the term “JP-T” as used herein means a published Japanese translation of a PCT patent application)

Patent Document 3: JP-A-2011-225814

Patent Document 4: JP-A-2011-52142

Patent Document 5: JP-T-2010-506406

Patent Document 6: JP-A-2007-45939

Patent Document 7: U.S. Patent Publication No. 2011/0318938

Patent Document 8: JP-A-8-53655

Patent Document 9: WO 2009/082833

Patent Document 10: JP-A-2009-102542

Patent Document 11: JP-A-2005-54140

### DISCLOSURE OF THE INVENTION

### Problems that the Invention is to Solve

In the case where a surface of semiconductor wafer provided with a device (that is, a device surface of device wafer) and a supporting substrate (that is, a carrier substrate) are temporarily adhered through a layer composed of the adhesive known in Patent Document 1 or the like, the adhesion of a certain strength is required for the adhesive layer in order to stably support the semiconductor wafer.

Therefore, in the case where the whole device surface of the semiconductor wafer and the supporting substrate are temporarily adhered through the adhesive layer, when the temporary adhesion between the semiconductor wafer and the supporting substrate is made sufficient in order to support the semiconductor wafer stably and without imparting damage to the semiconductor wafer, due to the too strong temporary adhesion between the semiconductor wafer and the supporting substrate, on the other hand, a disadvantage in that the device is damaged or in that the device is released from the semiconductor wafer is likely to occur, when the semiconductor wafer is released from the supporting substrate.

Also, the method of forming as a separation layer, a plasma polymer layer by a plasma deposition method between the wafer and the support layer system as in Patent Document 2 in order to prevent that the adhesion between the wafer and the support layer system becomes too strong has problems (1) in that the equipment cost for performing the plasma deposition method is ordinarily high, (2) in that the layer formation by the plasma deposition method takes time tbr vacuumization in the plasma apparatus and deposition of monomer, and (3) in that even when the separation layer composed of a plasma polymer layer is provided, it is not easy to control the adhesive strength in such a manner that the wafer is easily released from the separation layer in the case of releasing the supporting of wafer, while, on the other hand, the adhesive strength between the wafer and the separation layer maintains sufficiently in the case of supporting the wafer subjected to the processing.

Also, the method of releasing the temporary adhesion with heating as described in Patent Documents 3, 4 and 5, a disadvantage in that the device is damaged is likely to occur, when the semiconductor wafer is released.

Also, in the method of releasing the temporary adhesion by irradiation of active energy ray as described in Patent Documents 6, 7 and 8, it is necessary to use a supporting substrate which transmits the active energy ray.

The invention has been made in the light of the background described above, and an object of the invention is to provide a temporary adhesive for production of semiconductor device, which is excellent in coating property, which can temporarily support a member to be processed (for example, a semiconductor wafer) with a high adhesive force even under high temperature condition (for example, at 100° C.) when the member to be processed is subjected to a mechanical or chemical processing, which reduces a problem of generation of gas therefrom in the temporary support even under high temperature condition, and which can easily release (with high releasing property) the temporary support for the member processed without imparting damage to the member processed even after being subjected to a process at a high temperature, and an adhesive support and a production method of semiconductor device using the same.

### Means for Solving the Problems

As a result of the intensive investigations to solve the problems described above, the inventors have found that when an adhesive composition containing (A) a radical polymerizable monomer or oligomer containing a fluorine atom or a silicon atom, (B) a polymer compound, and (C) a radical polymerization initiator is used as a temporary adhesive in a temporary adhesion step of a semiconductor wafer and a supporting substrate, the coating property is excellent, a member to be processed can be temporarily supported with a high adhesive force even under high temperature condition (for example, at 100° C.), after processing the member to be processed, the temporary support for the member processed can be easily released by bringing the adhesive layer into contact with a release solvent without conducting heating or irradiation of active light or radiation as conducting in the prior art described above, although the reason for this is not quite clear. The inventors have also found that by using the temporary adhesive described above, the temporary support for the member processed can be easily released (with high releasing property) without imparting damage to the member processed, even after being subjected to the process at a high temperature in the production method of semiconductor device to complete the invention. Specifically, the invention includes the following items.

(1) A temporary adhesive for production of semiconductor device containing (A) a radical polymerizable monomer or oligomer containing a fluorine atom or a silicon atom, (B) a polymer compound, and (C) a radical polymerization initiator.
(2) The temporary adhesive for production of semiconductor device as described in (1) above, which further contains (D) a radical polymerizable monomer or oligomer which is different from the radical polymerizable monomer or oligomer (A).
(3) The temporary adhesive for production of semiconductor device as described in (1) or (2) above, wherein the radical polymerizable monomer or oligomer (A) has two or more radical polymerizable functional groups.
(4) The temporary adhesive for production of semiconductor device as described in any one of (1) to (3) above, wherein the radical polymerizable monomer or oligomer (A) is a radical polymerizable monomer or oligomer containing a fluorine atom.
(5) The temporary adhesive for production of semiconductor device as described in any one of (1) to (4) above, wherein the radical polymerization initiator (C) is a photo-radical polymerization initiator.
(6) The temporary adhesive for production of semiconductor device as described in any one of (1) to (5) above, which contains as the radical polymerization initiator (C), a photo-radical polymerization initiator and a heat radical polymerization initiator.
(7) An adhesive support comprising a substrate and on the substrate an adhesive layer formed from the temporary adhesive for production of semiconductor device as described in any one of (11) to (6) above.
(8) A production method of semiconductor device having a member processed comprising

a step of adhering a first surface of a member to be processed to a substrate through an adhesive layer formed from the temporary adhesive for production of semiconductor device as described in any one of (1) to (6) above,

a step of conducting a mechanical or chemical processing on a second surface which is different from the first surface of the member to be processed to obtain the member processed, and

a step of releasing the first surface of the member processed from the adhesive layer.

(9) The production method of semiconductor device as described in (8) above, which further comprises a step of irradiating active light or radiation, or heat to a surface of the adhesive layer which is to be adhered to the first surface of a member to be processed, before the step of adhering a first surface of a member to be processed to a substrate through the adhesive layer.
(10) The production method of semiconductor device as described in (8) or (9) above, which further comprises a step of heating the adhesive layer at a temperature from 50 to 300° C., after the step of adhering a first surface of a member to be processed to a substrate through the adhesive layer and before the step of conducting a mechanical or chemical processing on a second surface which is different from the first surface of the member to be processed to obtain the member processed.
(11) The production method of semiconductor device as described in any one of (8) to (10) above, wherein the step of releasing the first surface of the member processed from the adhesive layer includes a step of bringing the adhesive layer into contact with a release solution.
(12) The production method of semiconductor device as described in any one of (8) to (11) above, wherein the member to be processed comprises a substrate to be processed and a protective layer provided on a first surface of the substrate to be processed, a surface of the protective layer opposite to the substrate to be processed is the first surface of the member to be processed, and a second surface which is different from the first surface of the substrate to be processed is the second surface of the member to be processed.
(13) A kit comprising a compound for protective layer, and the temporary adhesive for production of semiconductor device as described in any one of (1) to (6) above.
(14) A kit comprising a compound for protective layer, a release solution, and the temporary adhesive for production of semiconductor device as described in any one of (1) to (6) above.

### Advantage of the Invention

According to the invention, a temporary adhesive for production of semiconductor device, which is excellent in coating property, which can temporarily support a member to be processed with a high adhesive force when the member to be processed is subjected to a mechanical or chemical processing, and which can easily release the temporary support for the member processed without imparting damage to the member processed even after being subjected to a process at a high temperature in the production method of semiconductor device, and an adhesive support and a production method of semiconductor device using the same can be provided.

### BRIEF DESCRIPTION OF THE DRAWING

FIG. 1A and FIG. 1B are a schematic cross-sectional view illustrating temporary adhesion of an adhesive support and a device wafer and a schematic cross-sectional view showing a state in which the device wafer temporarily adhered by the adhesive support is thinned, respectively.

FIG. 2 is a schematic cross-sectional view illustrating release of a temporary adhering state between a conventional adhesive support and a device wafer.

FIG. 3A, FIG. 3B, FIG. 3C and FIG. 3D are a schematic cross-sectional view illustrating temporary adhesion of an adhesive support and a device wafer provided with a protective layer, a schematic cross-sectional view showing a state in which the device wafer provided with a protective layer temporarily adhered by the adhesive support is thinned, a schematic cross-sectional view showing the thin device wafer provided with a protective layer released from the adhesive support and a schematic cross-sectional view showing the thin device wafer, respectively.

FIG. 4A and FIG. 4B are a schematic cross-sectional view illustrating a state in which the device wafer temporarily adhered by the adhesive support is thinned and a schematic cross-sectional view illustrating a state in which the device wafer provided with a protective layer temporarily adhered by the adhesive support is thinned, respectively.

FIG. 5A shows a schematic cross-sectional view illustrating exposure of the adhesive support, and FIG. 5B shows a schematic top view of a mask.

FIG. 6A shows a schematic cross-sectional view of the adhesive support subjected to pattern exposure, and FIG. 6B shows a schematic top view of the adhesive support subjected to pattern exposure.

FIG. 7 shows a schematic cross-sectional view illustrating irradiation of active light or radiation, or heat to the adhesive support.

### MODE FOR CARRYING OUT THE INVENTION

Embodiments of the invention will be described in detail hereinafter.

In the description of a group (atomic group) in the specification, when the group is described without specifying whether the group is substituted or unsubstituted, the group includes both a group (atomic group) having no substituent and a group (atomic group) having a substituent. For example, “an alkyl group” includes not only an alkyl group which has no substituent (an unsubstituted alkyl group) but also an alkyl group which has a substituent (a substituted alkyl group).

In the specification, the term “active light” or “radiation” includes, for example, visible light, an ultraviolet ray, a far ultraviolet ray, an electron beam and an X-ray. Also, the term “light” as used in the invention means active light or radiation.

Also, the term “exposure” in the specification includes, unless otherwise specified, not only exposure by a mercury lamp, an ultraviolet ray, a far ultraviolet ray represented by an excimer laser, an X-ray, EUV light and the like, but also drawing by a particle ray, for example, an electron beam or an ion beam.

Also, in the specification, the term “(meth)acrylate” represents both or either of acrylate and methacrylate, the term “(meth)acryl” represents both or either of acryl and methacryl, and the term “(meth)acryloyl” represents both or either of acryloyl and methacryloyl. Also, in the specification, the terms “monomer” and “monomer” have the same meaning. A monomer according to the invention is distinguished from an oligomer and a polymer, and means a compound having a weight average molecular weight of 2,000 or less. In the specification, a polymerizable compound indicates a compound having a polymerizable group, and may be a monomer or a polymer. The polymerizable group denotes a group which is involved in a polymerization reaction.

In the embodiments described below, the member or the like described in the drawing already referred to is indicated by the same or corresponding symbol in the figure and its description is simplified or omitted.

The temporary adhesive for production of semiconductor device (hereinafter, also simply referred to as a “temporary adhesive”) according to the invention contains (A) a radical polymerizable monomer or oligomer containing a fluorine atom or a silicon atom, (B) a polymer compound, and (C) a radical polymerization initiator.

In accordance with the temporary adhesive for production of semiconductor device according to the invention, a temporary adhesive for production of semiconductor device, which is excellent in coating property, which can temporarily support a member to be processed with a high adhesive force even under high temperature condition (for example, at 100° C.) when the member to be processed is subjected to a mechanical or chemical processing, and which can release the temporary support for the member processed without imparting damage to the member processed even after being subjected to the process at a high temperature can be obtained.

The temporary adhesive for production of semiconductor device according to the invention is preferred for forming a through-silicon electrode. The formation of through-silicon electrode will be described in detail later.

Hereinafter, each of the components which the temporary adhesive for production of semiconductor device according to the invention may contain will be described in detail.

### (A) Radical Polymerizable Monomer or Oligomer Containing Fluorine Atom or Silicon Atom

The temporary adhesive for production of semiconductor device according to the invention contains a radical polymerizable monomer or oligomer containing a fluorine atom or a silicon atom.

The radical polymerizable monomer or oligomer containing a fluorine atom or a silicon atom is preferably a radical polymerizable monomer or oligomer containing a fluorine atom.

### [Radical Polymerizable Monomer or Oligomer Containing Fluorine Atom]

The radical polymerizable monomer or oligomer containing a fluorine atom (hereinafter, also simply referred to as a “specific monomer or oligomer”) according to the invention is a radical polymerizable monomer or oligomer containing one or more fluorine atoms in its molecule, and preferably contains two or more fluorine atoms in its molecule. It is particularly preferred to have a group which is commonly referred to as a perfluoro group.

The radical polymerizable monomer or oligomer containing a fluorine atom or a silicon atom contains a radical polymerizable functional group. The radical polymerizable functional group is not particularly limited and preferably an unsaturated group (for example, an ethylenically unsaturated bond group).

The radical polymerizable monomer or oligomer containing a fluorine atom or a silicon atom preferably contains two or more radical polymerizable functional groups, because the releasing property of the temporary adhesive of the temporary support for the member processed after being subjected to the process at a high temperature is more increased.

The radical polymerizable monomer or oligomer containing a fluorine atom is preferably at least one compound selected from the compounds represented by structural formulae (1), (2), (3), (4) and (5) shown below.

CH₂═CR₁COOR₂R_{f} Structural Formula (1)

In structural formula (1), R₁ represents a hydrogen atom or a methyl group, R₂ represents —CₚH₂ₚ—, —C(CₚH₂ₚ₊₁)H—, —CH₂C(CₚH₂ₚ₊₁)H— or —CH₂CH₂O—, R_{f} represents —CₙF₂ₙ₊₁, —(CF₂)ₙH, —CₙF₂ₙ₊₁—CF₃, —(CF₂)ₚOCₙH₂ₙCᵢF₂ᵢ₊₁, —(CF₂)ₚOCₘH₂ₘCᵢF₂ᵢH, —N(CₚH₂ₚ₊₁)COCₙF₂ₙ₊₁ or —N(CₚH₂ₚ₊₁)SO₂CₙF₂ₙ₊₁, wherein p represents an integer from 1 to 10, n represents an integer from 1 to 16, m represents an integer from 0 to 10, and i represents an integer from 0 to 16.

CH₂═CFOR₉ Structural Formula (2)

In structural formula (2), R₉ represents a fluoroalkyl group having from 1 to 20 carbon atoms.

CH₂═CHR₉ Structural Formula (3)

In structural formula (3), R₉ represents a fluoroalkyl group having from 1 to 20 carbon atoms.

CH₂═CR₃COOR₅RⱼR₆OCOCR₄═CH₂ Structural Formula (4)

In structural formula (4), R₃ and R₄ each represents a hydrogen atom or a methyl group, R₅ and R₆ each represents —C_{q}H_{2q}—, —C(C_{q}H_{2q+1})H—, —CH₂C(C_{q}H_{2q+1})H— or —CH₂CH₂O—, Rⱼ represents —CₜF₂ₜ, wherein q represents an integer from 1 to 10, and t represents an integer from 1 to 16.

CH₂═CHR₇COOCH₂(CH₂Rₖ)CHOCOCR₈═CH₂ Structural Formula (5)

In structural formula (5), R₇ and R₈ each represents a hydrogen atom or a methyl group, Rₖ represents —C_{y}F_{2y+1}, and y represents an integer from 1 to 16.

The monomer represented by structural formula (1) includes, for example, CF₃(CF₂)₅CH₂CH₂OCOCH═CH₂, CF₃CH₂OCOCH═CH₂, CF₃(CF₂)₄CH₂CH₂OCOC(CH₃)═CH₂, C₇F₁₅CON(C₂H₅)CH₂OCOC(CH₃)═CH₂, CF₃(CF₂)₇SO₂N((CH₂)CH₂CH₂OCOCH═CH₂, CF₃(CF₂)₇SO₂N(C₃H₇)CH₂CH₂OCOCH═CH₂, C₂F₅SO₂N(C₃H₇)CH₂CH₂OCOC(CH₃)═CH₂, (CF₃)₂CF(CF₂)₆(CH₂)₃OCOCH═CH₂, (CF₃)₂CF(CF₂)₁₀(CH₂)₃OCOC(CH₃)═CH₂, CF₃(CF₂)₄CH(CH₃)OCOC(CH₃)═CH₂, CF₃CH₂OCH₂CH₂OCOCH═CH₂, C₂F₅(CH₂CH₂O)₂CH₂OCOCH═CH₂, (CF₃)₂CFO(CH₂)₅OCOCH═CH₂, CF₃(CF₂)₄OCH₂CH₂OCOC(CH₃)═CH₂, C₂F₅CON(C₂H₅)CH₂OCOCH═CH₂, CF₃(CF₂)₂CON(CH₃)CH(CH₃)CH₂OCOCH═CH₂, H(CF₂)₆C(C₂H₅)OCOC(CH₃)═CH₂, H(CF₂)₈CH₂OCOCH═CH₂, H(CF₂)₄CH₂OCOCH═CH₂, H(CF₂)CH₂OCOC(CH₃)═CH₂. CF₃(CF₂)₇SO₂N(CH₃)CH₂CH₂OCOC(CH₃)═CH₂, CF₃(CF₂)₇SO₂N(CH₃)(CH₂)₁₀OCOCH═CH₂, C₂F₅SO₂N(C₂H₅)CH₂CH₂OCOC(CH₃)═CH₂, CF₃(CF₂)₇SO₂N(CH₃)(CH₂)₄OCOCH═CH₂ and C₂F₅SO₂N(C₂H₅)C(C₂H₅)HCH₂OCOCH═CH₂. The monomers may be used one kind alone or in combination of two or more kinds.

The fluoroalkylated olefin represented by structural formula (2) or (3) includes, for example, C₃F₇CH═CH₂, C₄F₉CH═CH₂, C₁₀F₂₁CH═CH₂, C₃F₇OCF═CF₂, C₇F₁₅OCF═CF₂ and C₈F₁₇OCF═CF₂.

The monomer represented by structural formula (4) or (5) includes, for example, CH₂═CHCOOCH₂(CF₂)₃CH₂OCOCH═CH₂ and CH₂═CHCOOCH₂CH(CH₂C₈F₁₇)OCOCH═CH₂.

As the radical polymerixable monomer or oligomer containing a fluorine atom, an oligomer having a repeating unit containing a fluorine atom and a repeating unit containing a radical polymerizable functional group is also preferably used.

The repeating unit containing a fluorine atom is preferably a repeating unit represented by formula (6) or (7) shown below.

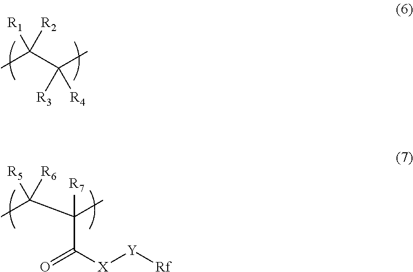

In formula (6), R₁, R₂, R₃ and R₄ each independently represents a hydrogen atom, a halogen atom, a hydroxy group or a monovalent organic group, provided that at least one of R₁, R₂, R₃ and R₄ is a fluorine atom or a monovalent organic group containing a fluorine atom.

The monovalent organic group containing a fluorine atom is not particularly limited and preferably a fluorine-containing alkyl group having from 1 to 30 carbon atoms, more preferably a fluorine-containing alkyl group having from 1 to 20 carbon atoms, and particularly preferably a fluorine-containing alkyl group having from 1 to 15 carbon atoms. The fluorine-containing alkyl group may have a straight-chain structure (for example, —CF₂CF₃, —CH₂(CF₂)₄H, —CH₂(CF₂)₈CF₃ or —CH₂CH₂(CF₂)₄H), a branched structure (for example, —CH(CF₃)₂, —CH₂CF(CF₃)₂, —CH(CH₃)CF₂CF₃ or —CH(CH₃)(CF₂)₅CF₂H), an alicyclic structure (preferably a 5-membered or 6-memebered alicyclic structure, for example, a perfluorocyclohexyl group, a perfluorocyclopentyl group or an alkyl group substituted with each of these groups), or an ether bond (for example, —CH₂OCH₂CF₂CF₃, —CH₂CH₂OCH₂C₄F₈H, —CH₂CH₂OCH₂CH₂C₈F₁₇ or —CH₂CF₂OCF₂CF₂OCF₂CF₂H). The fluorine-containing alkyl group may also be a perfluoroalkyl group.

The monovalent organic group is preferably an organic group constituting from 3-valent to 10-valent nonmetallic atoms and includes, for example, an organic group constituting from at least one element selected from 1 to 60 carbon atoms, 0 to 10 nitrogen atoms, 0 to 50 oxygen atoms, 1 to 100 hydrogen atoms and 0 to 20 sulfur atoms.

More specific examples of the monovalent organic group includes organic groups having the structures shown below and organic groups constituting from a combination of two or more of the structures shown below.

The monovalent organic group may have a substituent, and the substituent which may be introduced includes, for example, a halogen atom, a hydroxy group, a carboxyl group, a sulfonate group, a nitro group, a cyano group, an amido group, an amino group, an alkyl group, an alkenyl group, an alkynyl group, an aryl group, a substituted oxy group, a substituted sulfonyl group, a substituted carbonyl group, a substituted sulfinyl group, a sulfo group, a phosphono group, a phosphonate group, a silyl group and a heterocyclic group. The organic group also may contain an ether bond, an ester bond and a ureido bond.

The monovalent organic group is preferably an alkyl group, an alkenyl group, an alkynyl group or an aryl group. The alkyl group is preferably an alkyl group having from 1 to 8 carbon atoms, and includes, for example, a methyl group, an ethyl group, a propyl group, an octyl group, an isopropyl group, a tert-butyl group, an isopentyl group, a 2-ethylhexyl group, a 2-methylhexyl group and a cyclopentyl group. The alkenyl group is preferably an alkenyl group having from 2 to 20 carbon atoms, and includes, for example, a vinyl group, an allyl group, a prenyl group, a geranyl group and an oleyl group. The alkynyl group is preferably an alkynyl group having from 3 to 10 carbon atoms, and includes, for example, an ethynyl group, a propargyl group and a trimethylsilyl group. The aryl group is preferably an aryl group having from 6 to 12 carbon atoms, and includes, for example, a phenyl group, a 1-naphthyl group and a 2-naphthyl group. The heterocyclic group is preferably a heterocyclic group having from 2 to 10 carbon atoms, and includes, for example, a furanyl group, a thiophenyl group and a pyridyl group.

In formula (7), X represents an oxygen atom, a sulfur atom or —N(R₈)—, wherein R₈ represents a hydrogen atom or a monovalent organic group. The monovalent organic group includes, for example, an alkyl group which may have a substituent. Specific examples of the substituent are same as those of the substituent which the monovalent organic group represented by any of R₁ to R₄ may have.

Y represents a single bond or a divalent connecting group. The divalent connecting group includes a divalent connecting group selected from the group consisting of —CO—, —O—, —NH—, a divalent aliphatic group, a divalent aromatic group and a combination thereof.

R₅, R₄ and R₇ each independently represents a hydrogen atom, an alkyl group or a halogen atom.

R_{f} represents a fluorine atom or a monovalent organic group containing a fluorine atom. As the monovalent organic group containing a fluorine atom, the specific examples described for the monovalent organic group containing a fluorine atom in formula (6) are preferably used.

The content of the repeating unit containing a fluorine atom is preferably from 2 to 98% by mole, more preferably from 10 to 90% by mole, based on the total repeating units of the radical polymerizable oligomer containing a fluorine atom.

The repeating unit containing a radical polymerizable functional group is preferably a repeating unit represented by formula (8) shown below.

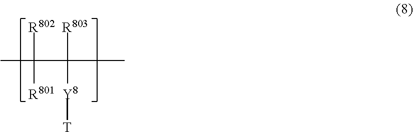

In formula (8), R⁸⁰¹ to R⁸⁰³ each independently represents a hydrogen atom, an alkyl group or a halogen atom. T represents a structure containing a radical polymerizable functional group. T preferably represents a radical polymerizable functional group represented by formula (9) shown below.

The alkyl group represented by any of R⁸⁰¹ to R⁸⁰³ is preferably an alkyl group having from 1 to 6 carbon atoms.

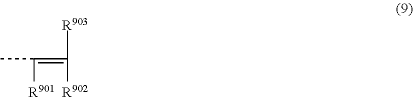

In formula (9), R⁹⁰¹ to R⁹⁰³ each independently represents a hydrogen atom, an alkyl group or an aryl group. The dotted line denotes a bond connecting to Y⁸.

The alkyl group is preferably an alkyl group having from 1 to 8 carbon atoms, and includes, for example, a methyl group, an ethyl group, a propyl group, an octyl group, an isopropyl group, a tert-butyl group, an isopentyl group, a 2-ethyhexyl group, a 2-methylhexyl group and a cyclopentyl group. The aryl group is preferably an aryl group having from 6 to 12 carbon atoms, and includes, for example, a phenyl group, a 1-naphthyl group and a 2-naphthyl group. Each of R⁹⁰¹ to R⁹⁰³ is preferably a hydrogen atom or a methyl group.

Y⁸ represents a single bond or a divalent connecting group selected from the group consisting of —CO—, —O—, —NH—, a divalent aliphatic group, a divalent aromatic group and a combination thereof. Specific examples of the combination of groups represented by Y⁸ are set forth below. In each of the specific examples shown below, the left side connects to the main chain and the right side connects to formula (9).

L1: —CO—NH-divalent aliphatic group-O—CO—NH-divalent aliphatic group-O—CO—

L2: —CO—NH-divalent aliphatic group-O—CO—

L3: —CO-divalent aliphatic group-O—CO—

L4: —CO—O-divalent aliphatic group-O—CO—

L5: -divalent aliphatic group-O—CO—

L6: —CO—NH-divalent aromatic group-O—CO—

L7: —CO-divalent aromatic group-O—CO—

L8: -divalent aromatic group-O—CO—

L9: —CO—O-divalent aliphatic group-CO—O-divalent aliphatic group-O—CO—

L10: —CO—O-divalent aliphatic group-O—CO-divalent aliphatic group-O—CO—

L11: —CO—O-divalent aromatic group-CO—O-divalent aliphatic group-O—CO—

L12: —CO—O-divalent aromatic group-O—CO-divalent aliphatic group-O—CO—

L13: —CO—O-divalent aliphatic group-CO—O-divalent aromatic group-O—CO—

L14: —CO—O-divalent aliphatic group-O—CO-divalent aromatic group-O—CO—

L15: —CO—O-divalent aromatic group-CO—O-divalent aromatic group-O—CO—

L16: —CO—O-divalent aromatic group-O—O-divalent aromatic group-O—CO—

L17: —CO—O-divalent aromatic group-O—CO—NH-divalent aliphatic group-O—CO—

L18: —CO—O-divalent aliphatic group-O—CO—NH-divalent aliphatic group-O—CO—

In the above, the divalent aliphatic group includes an alkylene group, a substituted alkylene group, an alkenylene group, a substituted alkenylene group, an alkenylene group, a substituted alkenylene group and a polyalkyleneoxy group. Among them, an alkylene group, a substituted alkylene group, an alkenylene group and a substituted alkenylene group are preferred, and an alkylene group and a substituted alkylene group are more preferred.

Of the divalent aliphatic groups, a chain structure is preferred than a cyclic structure, and further a straight-chain structure is preferred than a chain structure having a branch. A number of carbon atoms included in the divalent aliphatic group is preferably from 1 to 20, more preferably from 1 to 15, still more preferably from 1 to 12, yet still more preferably from 1 to 10, even yet still more preferably from 1 to 8, and particularly preferably from 1 to 4.

Examples of the substituent for the divalent aliphatic group include a halogen atom (e.g., F, Cl, Br or I), a hydroxy group, a carboxyl group, an amino group, a cyano group, an aryl group, an alkoxy group, an aryloxy group, an acyl group, an alkoxycarbonyl group, an aryloxycarbonyl group, an acyloxy group, a monoalkylamino group, a dialkylamino group, an arylamino group and a diarylamino group.

The divalent aromatic group includes, for example, a phenylene group, a substituted phenylene group, a naphthylene group and a substituted naphthylene group, and a phenylene group is preferred. Examples of the substituent for the divalent aromatic group include an alkyl group in addition to the substituents described for the divalent aliphatic group above.

The content of the repeating unit containing a radical polymerizable functional group is preferably from 2 to 98% by mole, more preferably from 10 to 90% by mole, based on the total repeating units of the radical polymerizable oligomer containing a fluorine atom.

The weight average molecular weight of the radical polymerizable oligomer containing a fluorine atom determined by a gel permeation chromatography (GPC) method and calculated in terms of polystyrene is preferably from 2,000 to 10,000, more preferably from 2,000 to 8,000, and most preferably from 2,000 to 6,000.

The content of the radical polymerizable monomer or oligomer containing a fluorine atom is not particularly limited and is preferably from 0.01 to 15% by weight, based on the total solid content of the temporary adhesive for production of semiconductor device. When it is less than 0.01% by weight, the releasing property may tend to be insufficient. On the other hand, when it exceeds 15% by weight, the adhesiveness may tend to decrease.

### [Radical Polymerizable Monomer or Oligomer Containing Silicon Atom]

The radical polymerizable monomer or oligomer containing a silicon atom according to the invention is preferably a silicone monomer or a silicone oligomer, and includes, for example, a compound wherein at least one terminal of polydimethylsiloxane bond is an ethylenically unsaturated group, for example, a (meth)acryloyl group or a styryl group. A compound having a (meth)acryloyl group is preferred.

The number average molecular weight of the radical polymerizable oligomer containing a silicon atom determined by a gel permeation chromatography method and calculated in terms of polystyrene is preferably from 1,000 to 10,000. When the number average molecular weight of the radical polymerizable oligomer containing a silicon atom determined by a gel permeation chromatography method and calculated in terms of polystyrene is less than 1,000 or more than 10,000, the property, for example, the releasing property due to the silicon atom may be hard to develop.

As the radical polymerizable monomer containing a silicon atom according to the invention, a compound represented by formula (11) or (12) shown below is preferably used.

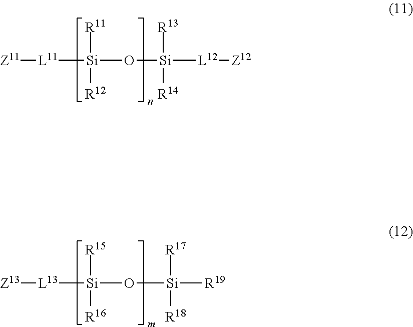

In formulae (11) and (12), R¹¹ to R¹⁹ each independently represents a hydrogen atom, an alkyl group, an alkoxy group, an alkoxycarbonyl group or an aryl group.

The alkyl group may be a straight-chain or branched form, is preferably an alkyl group having from 1 to 5 carbon atoms, and specifically includes, for example, a methyl group, an ethyl group, an n-propyl group and an isopropyl group. The alkoxy group is represented by —OR²⁰ wherein R²⁰ represents an alkyl group (preferably an alkyl group having from 1 to 5 carbon atoms), and specifically includes, for example, a methoxy group, an ethoxy group, a propoxy group, an isopropoxy group and a butoxy group. The alkoxycarbonyl group is represented by —C(═O)R₂₁ wherein R₂₁ represents an alkoxy group (preferably an alkoxy group having from 1 to 5 carbon atoms), and specifically includes, for example, a methoxycarbonyl group, an ethoxycarbonyl group and a propoxycarbonyl group. The aryl group includes, for example, a phenyl group, a tolyl group and a naphthyl group, and these groups may have a substituent and, for example, a phenylmethyl (benzyl) group, a phenylethyl group, a phenylpropyl group, a phenylbutyl group and a naphthylmethyl group are exemplified.

L¹¹, L¹² and L¹³ each independently represents a single bond or a divalent connecting group. The divalent connecting group includes a divalent connecting group selected from the group consisting of —CO—, —O—, —NH—, a divalent aliphatic group, a divalent aromatic group and a combination thereof.

n and m each represents an integer of 0 or more, and is preferably an integer from 0 to 100, and more preferably an integer from 0 to 50.

Z¹¹, Z¹² and Z¹³ each independently represents a radical polymerizable group, and is particularly preferably a functional group represented by any of formulae (i) to (iii) shown below.

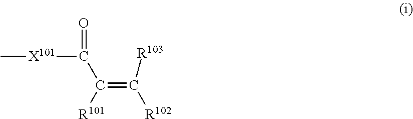

In formula (i), R¹⁰¹ to R¹⁰³ each independently represents a hydrogen atom or a monovalent organic group. R¹⁰¹ is preferably a hydrogen atom, an alkyl group which may have a substituent or the like, and among them, a hydrogen atom or a methyl group is preferred because of high radical reactivity. Each of R¹⁰² and R¹⁰³ is preferably a hydrogen atom, a halogen atom, an amino group, a carboxyl group, an alkoxycarbonyl group, a sulfo group, a nitro group, a cyano group, an alkyl group which may have a substituent, an aryl group which may have a substituent, an alkoxy group which may have a substituent, an aryloxy group which may have a substituent, an alkylamino group which may have a substituent, an arylamino group which may have a substituent, an alkylsulfonyl group which may have a substituent or an arylsulfonyl group which may have a substituent, and among them, a hydrogen atom, a carboxyl group, an alkoxycarbonyl group, an alkyl group which may have a substituent or an aryl group which may have a substituent is preferred because of high radical reactivity.

X¹⁰¹ represents an oxygen atom, a sulfur atom or —N(R₁₀₄)—, and R₁₀₄ represents a hydrogen atom or a monovalent organic group. The monovalent organic group includes an alkyl group which may have a substituent and the like. R₁₀₄ is preferably a hydrogen atom, a methyl group, an ethyl group or an isopropyl group because of high radical reactivity.

The substituent which may be introduced includes an alkyl group, an alkenyl group, an alkynyl group, an aryl group, an alkoxy group, an aryloxy group, a halogen atom, an amino group, an alkylamino group, an arylamino group, a carboxyl group, an alkoxycarbonyl group, a sulfo group, a nitro group, a cyano group, an amido group, an alkylsulfonyl group and an arylsulfonyl group.

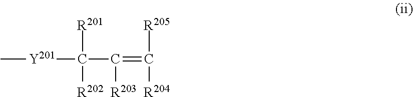

In formula (ii), R²⁰¹ to R²⁰⁵ each independently represents a hydrogen atom or a monovalent organic group. Each of R²⁰¹ to R²⁰⁵ is preferably represents a hydrogen atom, a halogen atom, an amino group, a carboxyl group, an alkoxycarbonyl group, a sulfo group, a nitro group, a cyano group, an alkyl group which may have a substituent, an aryl group which may have a substituent, an alkoxy group which may have a substituent, an aryloxy group which may have a substituent, an alkylamino group which may have a substituent, an arylamino group which may have a substituent, an alkylsulfonyl group which may have a substituent and an arylsulfonyl group which may have a substituent, and more preferably a hydrogen atom, a carboxyl group, an alkoxycarbonyl group, an alkyl group which may have a substituent or an aryl group which may have a substituent.

The substituent which may be introduced includes the substituents described in formula (i).

Y²⁰¹ represents an oxygen atom, a sulfur atom or —N(R₂₀₆)—. R₂₀₆ has the same meaning as R₁₀₄ in formula (i), and preferred examples thereof are also the same.

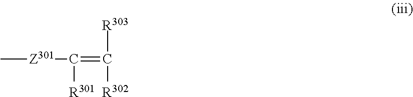

In formula (iii), R³⁰¹ to R³⁰³ each independently represents a hydrogen atom or a monovalent organic group. R³⁰¹ is preferably a hydrogen atom, an alkyl group which may have a substituent or the like, and among them, a hydrogen atom or a methyl group is preferred because of high radical reactivity. Each of R³⁰² and R³⁰³ is preferably a hydrogen atom, a halogen atom, an amino group, a carboxyl group, an alkoxycarbonyl group, a sulfo group, a nitro group, a cyano group, an alkyl group which may have a substituent, an aryl group which may have a substituent, an alkoxy group which may have a substituent, an aryloxy group which may have a substituent, an alkylamino group which may have a substituent, an arylamino group which may have a substituent, an alkylsulfonyl group which may have a substituent or an arylsulfonyl group which may have a substituent, and a hydrogen atom, a carboxyl group, an alkoxycarbonyl group, an alkyl group which may have a substituent or an aryl group which may have a substituent is preferred because of high radical reactivity.

The substituent which may be introduced includes the substituents described in formula (i). Z³⁰¹ represents an oxygen atom, a sulfur atom, —N(R₃₀₄)— or a phenylene group which may have a substituent. R₃₀₄ has the same meaning as R₁₀₄ in formula (i), and the monovalent organic group includes an alkyl group which may have a substituent and the like, and among them, a methyl group, an ethyl group or an isopropyl group is preferred because of high radical reactivity.

The content of the radical polymerizable monomer or oligomer containing a silicon atom is preferably from 0.01 to 15% by weight, based on the total solid content of the temporary adhesive for production of semiconductor device. When it is less than 0.01% by weight, the releasing property may tend to decrease. On the other hand, when it exceeds 15% by weight, the adhesiveness may tend to decrease.

As the radical polymerizable monomer or oligomer containing a fluorine atom or a silicon atom, for example, RS-75 and RS-72-K produced by DIC Corp., OPTOOL DAC-HP produced by Daikin Industries, Ltd., X-22-164, X-22-164AS, X-22-164A, X-22-164B, X-22-164C and X-22-164E produced by Shin-Etsu Chemical Co., Ltd., EBECRYL 350 and EBECRYL 1360 produced by Daicel-Cytec Co., Ltd., and TEGO Rad 2700 produced by Degussa Co. are exemplified.

### (B) Polymer Compound

The temporary adhesive for production of semiconductor device according to the invention is excellent in the coating property because of including a polymer compound. The coating property as used herein means uniformity of layer thickness after coating and film-forming property after coating.

According to the invention, an appropriate polymer compound may be used.

For instance, a synthetic resin, for example, a hydrocarbon resin, a novolac resin, a phenol resin, an epoxy resin, a melamine resin, a urea resin, an unsaturated polyester resin, an alkyd resin, polyurethane, polyimide, polyethylene, polypropylene, polyvinyl chloride, polyvinyl acetate, Teflon (registered trademark), an ABS resin, an AS resin, an MS resin, an acrylic resin, polyamide, polyacetal, polycarbonate, polyphenylene ether, polybutylene terephthalate, polyethylene terephthalate, polyphenylene sulfide, polysulfone, polyether sulfone, polyarylate, polyether ether ketone or polyamideimide, and a natural resin, for example, a natural rubber are exemplified. Of the resins, a hydrocarbon resin, an ABS resin, an AS resin, an MS resin, polyurethane, a novolac resin and a polyimide are preferred, and a hydrocarbon resin and an MS resin are most preferred.

According to the invention, the polymer compound may be used in combination of two or more thereof, if desired.

According to the invention, an appropriate hydrocarbon resin can be used.

The hydrocarbon resin according to the invention essentially means a resin composed of only carbon atoms and hydrogen atoms, but it may contain other atoms in its side chain as long as the essential skeleton is a hydrocarbon resin. Specifically, a case wherein a functional group other than a hydrocarbon group is directly connected to the main chain, for example, an acrylic resin, a polyvinyl alcohol resin, a polyvinyl acetal resin or a polyvinyl pyrrolidone resin is also included in the hydrocarbon resin according to the invention. In this case, the content of a repeating unit in which a hydrocarbon group is directly connected to the main chain is preferably 30% by mole or more based on the total repeating units of the resin.

The hydrocarbon resin which fulfils the condition described above includes, for example, a polystyrene resin, a terpene resin, a terpene phenol resin, a modified terpene resin, a hydrogenated terpene resin, a hydrogenated terpene phenol resin, rosin, a rosin ester, a hydrogenated rosin, a hydrogenated rosin ester, a polymerized rosin, a polymerized rosin ester, a modified rosin, a rosin-modified phenol resin, an alkylphenol resin, an aliphatic petroleum resin, an aromatic petroleum resin, a hydrogenated petroleum resin, a modified petroleum resin, an alicyclic petroleum resin, a coumarone petroleum resin, an indene petroleum resin, a styrene-olefin copolymer, an olefin polymer (for example, a methylpentene copolymer), and a cycloolefin polymer (for example, a norbornene copolymer, a dicyclopentadiene copolymer or a tetracyclododecene copolymer).

The hydrocarbon resin is preferably a polystyrene resin, a terpene resin, rosin, a petroleum resin, a hydrogenated rosin, a polymerized rosin, an olefin polymer or a cycloolefin polymer, more preferably a polystyrene resin, a terpene resin, rosin, an olefin polymer or a cycloolefin polymer, still more preferably a polystyrene resin, a terpene resin, rosin, an olefin polymer, a polystyrene resin or a cycloolefin polymer, particularly preferably a polystyrene resin, a terpene resin, rosin, a cycloolefin polymer and an olefin polymer, and most preferably a polystyrene resin or a cycloolefin polymer.

The cycloolefin polymer includes, for example, a norborene polymer, a polymer of monocyclic cycloolefin, a polymer of cyclic conjugated diene, vinyl alicyclic hydrocarbon polymer and hydrogenated compounds of these polymers. Preferred examples of the cycloolefin polymer include an addition (co)polymer containing at least one repeating unit represented by formula (II) shown below and an addition (co)polymer further containing at least one repeating unit represented by formula (I) shown below. Also, other preferred examples of the cycloolefin polymer include a ring-opening (co)polymer containing at least one cyclic repeating unit represented by formula (III) shown below.

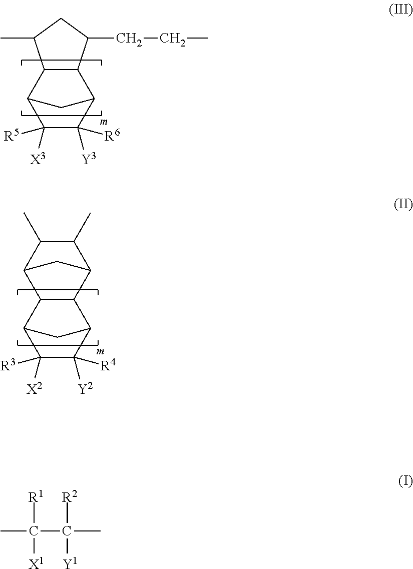

In the formulae, m represents an integer from 0 to 4, R¹ to R⁶ each independently represents a hydrogen atom or a hydrocarbon group having from 1 to 10 carbon atoms, X¹ to X³ and Y⁸ to Y³ each independently represents a hydrogen atom, a hydrocarbon group having from 1 to 10 carbon atoms, a halogen atom, a hydrocarbon group having from 1 to 10 carbon atoms substituted with a halogen atom, —(CH₂)ₙCOOR₁₁, —(CH₂)ₙOCOR₁₂, —(CH₂)ₙNCO, —(CH₂)ₙNO₂, —(CH₂)ₙCN, —(CH₂)ₙCONR₁₃R₁₄, —(CH₂)ₙNR₁₅R₁₆, —(CH₂)ₙOZ, —(CH₂)ₙW, or (—CO)₂O or (—CO)₂NR₁₇, each of which is constituted with X₁ and Y₁, X₂ and Y₂ or X₃ and Y₃, R₁₁, R₁₂, R₁₃, R₁₄, R₁₅, R₁₆ and R₁₇ each independently represents a hydrogen atom or a hydrocarbon group (preferably a hydrocarbon group having from 1 to 20 carbon atoms), Z represents a hydrocarbon group or a hydrocarbon group substituted with a halogen atom, W represents SiR₁₈ₚD₃₋ₚ (R₁₈ represents a hydrocarbon group having from 1 to 10 carbon atoms, D represents a halogen atom, —OCOR₁₈ or —OR₁₈, p represents an integer from 0 to 3), and n represents an integer from 0 to 10.

The norbornene polymers are disclosed, for example, in JP-A-10-7732, JP-T-2002-504184, U.S. Patent Publication No. 2004/0229157 and WO 2004/070463. The norbornene polymer is obtained by addition polymerization of norbornene polycyclic unsaturated compounds to each other. Also, if desired, the norbornene polycyclic unsaturated compound can be addition-polymerized with ethylene, propylene, butene; a conjugated diene, for example, butadiene or isoprene; or a non-conjugated diene, for example, ethylidene norbornene. The norbornene polymer is marketed under the trade name of APEL from Mitsui Chemicals, Inc. including the grades having different glass transition temperature (Tg), for example, APL 8008T (Tg: 70° C.), APL 6013T (Tg: 125° C.) and APL 6015T (Tg: 145° C.). Pellets, for example, TOPAS 8007, TOPAS 5013, TOPAS 6013 and TOPAS 6015 are marketed from Polyplastics Co., Ltd.

Further, APPEAR 3000 is marketed from Ferrania S.p.A.

The hydrogenated product of norbornene polymer can be produced by addition polymerization or metathesis ring opening polymerization of the polycyclic unsaturated compound, followed by hydrogenation as disclosed, for example, in JP-A-1-240517, JP-A-7-196736, JP-A-60-26024, JP-A-62-19801, JP-A-2003-159767 and JP-A-2004-309979.

In formula (III), each of R⁵ and R⁶ is preferably a hydrogen atom or a methyl group, each of X³ and Y³ is preferably a hydrogen atom, and other groups are appropriately selected. The norbornene polymers are marketed under the trade names of ARTON G and ARTON F from JSR Corp., and under the trade names of ZEONOR ZF14. ZEONOR ZF16, ZEONEX 250, ZEONEX 280 and ZEONEX 480R from Zeon Corp., and these can be used.

The weight average molecular weight of the polymer compound determined by a gel permeation chromatography (GPC) method and calculated in terms of polystyrene is preferably from 10,000 to 1,000,000, more preferably from 50,000 to 500,000, and still more preferably from 100,000 to 300,000.

The content of the polymer compound is preferably 5% by weight or more, more preferably 10% by weight or more, still more preferably more than 20% by weight, based on the total solid content of the temporary adhesive according to the invention.

Also, the content of the polymer compound is preferably 70% by weight or less, more preferably 60% by weight or less, still more preferably 50% by weight or less, based on the total solid content of the temporary adhesive according to the invention.

### (C) Radical Polymerization Initiator

The temporary adhesive for production of semiconductor device according to the invention contains a radical polymerization initiator, that is, a compound which generates a radical upon irradiation of active light or radiation (light irradiation) or heat.

By incorporating the radical polymerization initiator into the temporary adhesive for production of semiconductor device according to the invention, when the adhesive layer is irradiated with light or heated, a curing reaction occurs due to the radical, whereby the adhesiveness in the light-irradiated or heated portion can be decreased. When the light irradiation or heating is conducted, for example, in the central area of the adhesive layer to leave the adhesiveness only in the peripheral area, since the area of the adhesive layer to be dissolved by solvent immersion at the time of releasing becomes small, there is an advantage in that the time necessary for releasing can be shortened.

As the compound which generates a radical upon irradiation of active light or radiation (hereinafter, also simply referred to as a photo-radical polymerization initiator), for example, compounds known as polymerization initiators described below can be used.

The polymerization initiator is not particularly limited as long as it has an ability to initiate a polymerization reaction (crosslinking reaction) of a reactive compound having a polymerizable group as the polymerizable monomer described above, and can be appropriately selected from known polymerization initiators. For example, a polymerization initiator having photosensitivity to light from an ultraviolet region to a visible region is preferred. Also, the polymerization initiator may be an activator which causes any action with a photo-excited sensitizer to produce an active radical.

Further, it is preferred that the polymerization initiator contains at least one compound having a molecular absorption coefficient of at least about 50 within the range from about 300 to 800 nm (preferably from 330 to 500 nm).

As the polymerization initiator, known compounds are used without limitation. The polymerization initiator includes, for example, a halogenated hydrocarbon derivative (for example, a compound having a triazine skeleton, a compound having an oxadiazole skeleton or a compound having a trihalomethyl group), an acylphosphine compound, for example, an acylphosphine oxide, a hexaarylbiimidazole, an oxime compound, for example, an oxime derivative, an organic peroxide, a thio compound, a ketone compound, an aromatic onium salt, a ketoxime ether, an aminoacetophenone compound, a hydroxyacetophenone, an azo compound, an azide compound, a metallocene compound, an organic boron compound, and an iron arene complex.

The halogenated hydrocarbon compound having a triazine skeleton includes, for example, compounds described in Wakabayashi et al., Bull. Chem. Soc. Japan, 42, 2924 (1969), compounds described in British Patent 1,388,492, compounds described in JP-A-53-133428, compounds described in German Patent 3,337,024, compounds described in F. C. Schaefer et al., J. Org. Chem., 29, 1527 (1964), compounds described in JP-A-62-58241, compounds described in JP-A-5-281728, compounds described in JP-A-5-34920, and compounds described in U.S. Pat. No. 4,212,976.

The compounds described in U.S. Pat. No. 4,212,976 include, for example, a compound having an oxadiazole skeleton (for example, 2-trichloromethyl-5-phenyl-1,3,4-oxadiazole, 2-trichloromethyl-5-(4-chlorophenyl)-1,3,4-oxadiazole, 2-trichloromethyl-5-(1-naphthyl)-1,3,4-oxadiazole, 2-trichloromethyl-5-(2-naphthyl)-1,3,4-oxadiazole, 2-tribromomethyl-5-phenyl-1,3,4-oxadiazole, 2-tribromomethyl-5-(2-naphthyl)-1,3,4-oxadiazole, 2-trichloromethyl-5-styryl-1,3,4-oxadiazole, 2-trichloromethyl-5-(4-chlorostyryl)-1,3,4-oxadiazole, 2-trichloromethyl-5-(4-methoxystyryl)-1,3,4-oxadiazole, 2-trichloromethyl-5-(1-naphthyl)-1,3,4-oxadiazole, 2-trichloromethyl-5-(4-n-buthoxystyryl)-1,3,4-oxadiazole or 2-tribromomethyl-5-styryl-1,3,4-oxadiazole).

Also, examples of the polymerization initiator other than the polymerization initiators described above include an acridine derivative (for example, 9-phenylacridine or 1,7-bis(9,9′-acridinyl)heptane), N-phenylglycine, a polyhalogen compound (for example, carbon tetrabromide, phenyl tribromomethyl sulfone or phenyl trichloromethyl ketone), a coumarin (for example, 3-(2-benzofuranoyl)-7-diethylaminocoumarin, 3-(2-benzofuroyl)-7-(1-pyrrolidinyl)coumarin, 3-benzoyl-7-diethylaminocoumarin, 3-(2-methoxybenzoyl)-7-diethylaminocoumarin, 3-(4-dimethylaminobenzoyl)-7-diethylaminocoumarin, 3,3′-carbonylbis(5,7-di-n-propoxycoumarin), 3,3′-carbonylbis(7-diethylaminocoumarin), 3-benzoyl-7-methoxycoumarin, 3-(2-furoyl)-7-diethylaminocoumarin, 3-(4-diethylaminocinnamoyl)-7-diethylaminocoumarin, 7-methoxy-3-(3-pyridylcarbonyl)coumarin, 3-benzoyl-5,7-dipropoxycoumarin, 7-benzotriazol-2-ylcoumarin, coumarin compounds described, for example, in JP-A-5-19475, JP-A-7-271028, JP-A-2002-363206, JP-A-2002-363207, JP-A-2002-363208 and JP-A-2002-363209), an acylphosphine oxide (for example, bis(2,4,6-trimethylbenzoyl)phenylphosphine oxide, bis(2,6-dimethoxybenzoyl)-2,4,4-trimethylpentylphenylphosphine oxide or LUCIRIN TPO), a metallocene (for example, bis(η5-2,4-cyclopentadien-1-yl)-bis(2,6-difluoro-3-(1H-pyrrol-1-yl)phenyl)titanium or η5-cyclopentadienyl-η6-cumenyl-iron(1+)-hexafluorophosphate(1−)), compounds described in JP-A-53-133428, JP-B-57-1819 (the term “JP-B” as used herein means an “examined Japanese patent publication”). JP-B-57-6096 and U.S. Pat. No. 3,615,455.

The ketone compound includes, for example, benzophenone, 2-methylbenzophenone, 3-methylbenzophenone, 4-methylbenzophenone, 4-methoxybenzophenone, 2-chlorobenzophenone, 4-chlorobenzophenone, 4-bromobenzophenone, 2-carboxybenzophenone, 2-ethoxycarbonylbenzophenone, benzophenone tetracarboxylic acid or tetramethyl ester thereof, a 4,4′-bis(dialkylamino)benzophenone (for example, 4,4′-bis(dimethylamino)benzophenone, 4,4′-bis(dicyclohexylamino)benzophenone, 4,4′-bis(diethylamino)benzophenone or 4,4′-bis(dihydroxyethylamino)benzophenone), 4-methoxy-4′-dimethylaminobenzophenone, 4,4′-dimethoxybenzophenone, 4-dimethylaminobenzophenone, 4-dimethylaminoacetophenone, benzyl, anthraquinone, 2-tert-butylanthraquinone, 2-methylanthraquinone, phenanthraquinone, xanthone, thioxanthone, 2-chlorothioxanthone, 2,4-diethylthioxanthone, fluorenone, 2-benzyldimethylamino-1-(4-morpholinophenyl-1-butanone, 2-methyl-1-[4-(methylthio)phenyl]-2-morpholino-1-propanone, 2-hydroxy-2-methyl-[4-(1-methylvinyl)phenyl]propanol oligomer, benzoin, a benzoin ether (for example, benzoin methyl ether, benzoin ethyl ether, benzoin propyl ether, benzoin isopropyl ether, benzoin phenyl ether or benzyl dimethyl ketal), acridone, chloroacridone, N-methylacridone, N-butylacridone and N-butylchloroacridone.

As a commercially available product, KAYACURE DETX (produced by Nippon Kayaku Co., Ltd.) is preferably used.

As the photopolymerization initiator, a hydroxyacetophenone compound, an aminoacetophenone compound and an acylphosphine compound can also be preferably used. More specifically, for example, an aminoacetophenone initiator described in JP-A-10-291969 and an acylphosphine oxide initiator described in Japanese Patent No. 4225898 can also be used.

As the hydroxyacetophenone initiator, IRGACURE 184, DAROCUR 1173, IRGACURE 500, IRGACURE 2959 and IRGACURE 127 (trade names, produced by BASF Corp.) can be used. As the aminoacetophenone initiator, commercially available products of IRGACURE 907. IRGACURE 369 and IRGACURE 379 (trade names, produced by BASF Corp.) can be used. As the aminoacetophenone initiator, compounds described in JP-A-2009-191179, where the absorption wavelength matches the light source having a long wavelength, for example, 365 nm or 405 nm, can also be used. Also, as the acylphosphine initiator, commercially available products of IRGACURE 819 and DAROCUR TPO (trade names, produced by BASF Corp.) can be used.

The photopolymerization initiator more preferably includes an oxime compound. As specific examples of the oxime initiator, compounds described in JP-A-2001-233842, compounds describe in JP-A-2000-80068 and compounds described in JP-A-2006-342166 can be used.

Examples of the oxime compound, for example, an oxime derivative, which is preferably used as the polymerization initiator according to the invention include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one and 2-ethoxycarbonyloxyimino-1-phenylpropan-1-one.

The oxime ester compound includes, for example, compounds described in J. C. S. Perkin II, (1979) pp. 1653-1660, J. C. S. Perkin II, (1979) pp. 156-162, Journal of Photopolymer Science and Technology, (1995) pp 202-232. JP-A-2000-66385, JP-A-2000-80068, JP-T-2004-534797 and JP-A-2006-342166.

As the commercially available product, IRGACURE OXE 01 (produced by BASF Corp.) and IRGACURE OXE 02 (produced by BASF Corp.) are also preferably used.

In addition, as the oxime ester compound other than the oxime ester compounds described above, compounds described in JP-T-2009-519904, wherein oxime is connected to the N-position of carbazole, compounds described in U.S. Pat. No. 7,626,957, wherein a hetero-substituent is introduced into the benzophenone moiety, compounds described in JP-A-2010-15025 and U.S. Patent Publication No. 2009/0292039, wherein a nitro group is introduced into the dye moiety, ketoxime compounds described in WO 2009/131189, compounds containing a triazine skeleton and an oxime skeleton in the same molecule described in U.S. Pat. No. 7,556,910, and compounds having an absorption maximum at 405 nm and exhibiting good sensitivity for a g-line light source described in JP-A-2009-221114 may also be used.

Furthermore, cyclic oxime compounds described in JP-A-2007-231000 and JP-A-2007-322744 can also be preferably used. Of the cyclic oxime compounds, cyclic oxime compounds condensed to a carbazole dye described in JP-A-2010-32985 and JP-A-2010-185072 have high light absorptivity and thus are preferred from the standpoint of high sensitivity.

Further, compounds described in JP-A-2009-242469 having an unsaturated bond at a specific site of an oxime compound can achieve high sensitivity by regenerating an active radical from a polymerization inactive radical, and thus are preferably used.

Oxime compounds having a specific substituent described in JP-A-2007-269779 and oxime compounds having a thioaryl group described in JP-A-2009-191061 are most preferred.

The molar absorption coefficient of the compound can be measured by using a known method, and specifically, it is preferred that the molar absorption coefficient is measured, for example, by an ultraviolet and visible spectrophotometer (Carry-5 Spectrophotometer produced by Varian, Inc.) using an ethyl acetate solvent at a concentration of 0.01 g/L.

From the standpoint of exposure sensitivity, the photo-radical polymerization initiator is preferably a compound selected from the group consisting of a trihalomethyltriazine compound, a benzyl dimethyl ketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound and a derivative thereof, a cyclopentadiene-benzene-iron complex and a salt thereof, a halomethyloxadiazole compound and a 3-aryl-substituted coumarin compound.

A trihalomethyltriazine compound, an α-aminoketone compound, an acylphosphine compound, a phosphine oxide compound, an oxime compound, a triarylimidazole dimer, an onium compound, a benzophenone compound or an acetophenone compound is more preferred, and at least one compound selected from the group consisting of a trihalomethyltriazine compound, an α-aminoketone compound, an oxime compound, a triarylimidazole dimer and a benzophenone compound is most preferred. It is most preferred to use an oxime compound.

As the compound which generates a radical upon heat (hereinafter, also simply referred to as a heat radical polymerization initiator), known heat radical generators can be used.

The heat radical polymerization initiator is a compound which generates a radical with heat energy to initiate or accelerate the polymerization reaction of the polymerizable monomer. By the addition of the heat radical polymerization initiator, in the case where after irradiating heat to the adhesive layer formed by using the temporary adhesive, the temporary adhesion of the member to be processed and the adhesive support is performed, the crosslinking reaction in the reactive compound having a crosslinkable group proceeds by the heat so that the adhesion property (that is, adherence property and tacking property) of the adhesive layer can be previously reduced as described in detail below.

On the other hand, in the case where after performing the temporary adhesion of the member to be processed and the adhesive support, heat is irradiated to the adhesive layer of the adhesive support, the crosslinking reaction in the reactive compound having a crosslinkable group proceeds by the heat so that the adhesive layer becomes more tough to prevent cohesion failure of the adhesive layer, which may likely occur when the member to be processed is subjected to a mechanical or chemical processing. Specifically, the adhesion property of the adhesive layer can be increased.

As a preferred heat radical polymerization initiator, the compound which generates a radical upon irradiation of active light or radiation as described above is exemplified, and a compound having a heat decomposition point ranging from 130 to 250° C., preferably from 150 to 220° C., is preferably used.

Examples of the heat radical polymerization initiator include an aromatic ketone, an onium salt compound, an organic peroxide, a thio compound, a hexaarylbiimidazole compound, a ketoxime ester compound, a borate compound, an azinium compound, a metallocene compound, an active ester compound, a compound having a carbon-halogen bond and an azo compound. Among them, an organic peroxide and an azo compound are more preferred, and an organic peroxide is particularly preferred.

Specifically, compounds described in Paragraph Nos. [0074] to [0118] of JP-A-2008-63554 are exemplified.

In the case where the temporary adhesive according to the invention contains as the radical polymerization initiator (C), a heat radical polymerization initiator (more preferably, a photo-radical polymerization initiator and a heat radical polymerization initiator), the adhesion property, particularly at high temperature (for example, 100° C.) can be more increased.

The temporary adhesive according to the invention preferably contains a photo-radical polymerization initiator.

The temporary adhesive according to the invention may contain one kind or two or more kinds of the radical polymerization initiators.

The content (total content in the case of using two or more kinds) of the radical polymerization initiator according to the invention is preferably from 0.1 to 50% by weight, more preferably from 0.1 to 30% by weight, still more preferably 0.1 to 20% by weight, based on the total solid content of the temporary adhesive.

(D) Radical Polymerizable Monomer or Oligomer which is Different from Radical Polymerizable Monomer or Oligomer (A)

The temporary adhesive according to the invention preferably further contains a radical polymerizable monomer or oligomer which is different from the radical polymerizable monomer or oligomer (A), that is, a radical polymerizable monomer or oligomer which does not contain a fluorine atom or a silicon atom (hereinafter, also simply referred to as an “other radical polymerizable monomer or oligomer”) in addition to the radical polymerizable monomer or oligomer containing a fluorine atom or a silicon atom (A).

The other radical polymerizable monomer or oligomer has a radical polymerizable functional group. The radical polymerizable functional group typically means a group capable of polymerizing by an action of a radical.

The radical polymerizable functional group is preferably, for example, a funmctional group capable of undergoing an addition polymerization reaction, and the functional group capable of undergoing an addition polymerization reaction includes, for example, an ethylenically unsaturated bond group, an amino group and an epoxy group. The radical polymerizable functional group may also be a functional group capable of generating a radical upon light irradiation, and such a radical polymerizable functional group includes, for example, a thiol group and a halogen group. Among them, as the radical polymerizable functional group, an ethylenically unsaturated bond group is preferred. As the ethylenically unsaturated bond group, a styryl group, a (meth)acryloyl group or an allyl group is preferred.

The other radical polymerizable monomer or oligomer preferably has two or more radical polymerizable functional groups, and this enables further improvement in the adhesion property of the temporary adhesive.

The other radical polymerizable oligomer preferably includes a homopolymer composed of a repeating unit containing a radical polymerizable functional group (for example, the repeating unit represented by formula (8) described with respect to the radical polymerizable oligomer containing a fluorine atom), and a copolymer including a repeating unit containing a radical polymerizable functional group and a repeating unit not containing a radical polymerizable functional group (for example, a repeating unit corresponding to a polymerizable compound having one polymerizable group among the radical polymerizable compound (B1) and the ionic polymerizable compound (B2) described in detail below).

In the other radical polymerizable oligomer, the content of the repeating unit containing a radical polymerizable functional group is preferably from 2 to 98% by mole, more preferably from 10 to 90% by mole, based on the total repeating units of the other radical polymerizable oligomer.

The content of the repeating unit not containing a radical polymerizable functional group is preferably from 2 to 98% by mole, more preferably from 10 to 90% by mole, based on the total repeating units of the other radical polymerizable oligomer.

The weight average molecular weight of the other radical polymerizable oligomer determined by a gel permeation chromatography (GPC) method and calculated in terms of polystyrene is preferably from 2,000 to 10,000, more preferably from 2,000 to 8,000, and most preferably from 2,000 to 6,000.

The other radical polymerizable monomer is typically a low molecular weight compound, and is preferably a low molecular weight compound having a molecular weight of 2,000 or less, more preferably a low molecular weight compound having a molecular weight of 1,500 or less, and still more preferably a low molecular weight compound having a molecular weight of 900 or less. The molecular weight of the monomer is ordinarily 100 or more.

The other radical polymerizable monomer specifically includes a radical polymerizable compound (B1) and an ionic polymerizable compound (B2).

The radical polymerizable compound (B1) is specifically selected from compounds having at least one, preferably two or more radical polymerizable groups. Such compounds are widely known in the field of art and they can be used in the invention without any particular limitation. The compound has a chemical form, for example, a monomer, a prepolymer, specifically, a dimer, a trimer or an oligomer, or a mixture thereof or a multimer thereof. The radical polymerizable compounds may be used individually or in combination of two or more thereof in the invention.

The radical polymerizable group is preferably an ethylenically unsaturated group. As the ethylenically unsaturated group, a styryl group, a (meth)acryloyl group or an allyl group is preferred.

More specifically, examples of the monomer and prepolymer include an unsaturated carboxylic acid (for example, acrylic acid, methacrylic acid, itaconic acid, crotonic acid, isocrotonic acid or maleic acid) and an ester, amide or multimer thereof. Preferably, an ester of an unsaturated carboxylic acid with a polyhydric alcohol compound, an amide of an unsaturated carboxylic acid with a polyvalent amine compound and a multimer thereof are exemplified. An addition reaction product of an unsaturated carboxylic acid ester or amide having a nucleophilic substituent, for example, a hydroxy group, an amino group or a mercapto group, with a monofunctional or polyfunctional isocyanate or epoxy, or a dehydration condensation reaction product of the unsaturated carboxylic acid ester or amide with a monofunctional or polyfunctional carboxylic acid is also preferably used. Further, an addition reaction product of an unsaturated carboxylic acid ester or amide having an electrophilic substituent, for example, an isocyanate group or an epoxy group with a monofunctional or polyfunctional alcohol, amine or thiol, or a substitution reaction product of an unsaturated carboxylic acid ester or amide having a releasable substituent, for example, a halogen group or a tosyloxy group with a monofunctional or polyfunctional alcohol, amine or thiol is also preferred. As other examples, compounds in which the unsaturated carboxylic acid described above is replaced by an unsaturated phosphonic acid, a vinylbenzene derivative, for example, styrene, vinyl ether, allyl ether or the like may also be used.

With respect to specific examples of the monomer, which is an ester of a polyhydric alcohol compound with an unsaturated carboxylic acid, as an acrylic acid ester, for example, ethylene glycol diacrylate, triethylene glycol diacrylate, 1,3-butanediol diacrylate, tetramethylene glycol diacrylate, propylene glycol diacrylate, neopentyl glycol diacrylate, trimethylolpropane triacrylate, trimethylolpropane tri(acryloyloxypropyl) ether, trimethylolethane triacrylate, hexanediol diacrylate, 1,4-cyclohexanediol diacrylate, tetraethylene glycol diacrylate, pentaerythritol diacrylate, pentaerythritol triacrylate, dipentaerythritol diacrylate, dipentaerythritol hexaacrylate, pentaerythritol tetraacrylate, sorbitol triacrylate, sorbitol tetraacrylate, sorbitol pentaacrylate, sorbitol hexaacrylate, tri(acryloyloxyethyl) isocyanurate, isocyanuric acid ethylene oxide (EO) modified triacrylate and polyester acrylate oligomer are exemplified.

As a methacrylic acid ester, for example, tetramethylene glycol dimethacrylate, triethylene glycol dimethacrylate, neopentyl glycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis[p-(3-methacryloxy-2-hydroxypropoxy)phenyl]dimethylmethane and bis[p-(methacryloxyethoxy)phenyl]dimethylmethane are exemplified.

As an itaconic acid ester, for example, ethylene glycol diitaconate, propylene glycol diitaconate, 1,3-butanediol diitaconate, 1,4-butanediol diitaconate, tetramethylene glycol diitaconate, pentaerythritol diitaconate and sorbitol tetraitaconate are exemplified.

As a crotonic acid ester, for example, ethylene glycol dicrotonate, tetramethylene glycol dicrotonate, pentaerythritol dicrotonate and sorbitol tetracrotonate are exemplified.

As an isocrotonic acid ester, for example, ethylene glycol diisocrotonate, pentaerythritol diisocrotonate and sorbitol tetraisocrotonate are exemplified.

As a maleic acid ester, for example, ethylene glycol dimaleate, triethylene glycol dimaleate, pentaerythritol dimaleate or sorbitol tetramaleate are exemplified.

As other examples of the ester, aliphatic alcohol esters described in JP-B-46-27926, JP-B-51-47334 and JP-A-57-196231, esters having an aromatic skeleton described in JP-A-59-5240, JP-A-59-5241 and JP-A-2-226149, and esters containing an amino group described in JP-A-1-165613.

Specific examples of the monomer, which is an amide of a polyvalent amine compound with an unsaturated carboxylic acid, include methylene bisacrylamide, methylene bismethacrylamide, 1,6-hexamethylene bisacrylamide, 1,6-hexamethylene bismethacrylamide, diethylenetriamine trisacrylamide, xylylene bisacrylamide and xylylene bismethacrylamide.

Other preferred examples of the amide monomer include amides having a cyclohexylene structure described in JP-B-54-21726.

Urethane type addition polymerizable compounds produced using an addition reaction between an isocyanate and a hydroxy group are also preferably used, and specific examples thereof include vinylurethane compounds having two or more polymerizable vinyl groups per molecule obtained by adding a vinyl monomer containing a hydroxy group represented by formula (A) shown below to a polyisocyanate compound having two or more isocyanate groups per molecule, described in JP-B-48-41708.

CH₂═C(R₄)COOCH₂CH(R₅)OH (A)

wherein R₄ and R₅ each independently represents H or CH₃.

Also, urethane acrylates described in JP-A-51-37193, JP-B-2-32293 and JP-B-2-16765, and urethane compounds having an ethylene oxide skeleton described in JP-B-58-49860, JP-B-56-17654, JP-B-62-39417 and JP-B-62-39418 are preferably used.

Also, as the radical polymerizable monomer, compounds described in Paragraph Nos. [0095] to [0108] of JP-A-2009-288705 are preferably used in the invention.

Also, as the radical polymerizable compound, a compound having an ethylenically unsaturated group which contains at least one addition polymerizable ethylene group and has a boiling point of 100° C. or more under normal pressure is also preferred. Examples thereof include a monofunctional acrylate or methacrylate, for example, polyethylene glycol mono(meth)acrylate, polypropylene glycol mono(meth)acrylate or phenoxyethyl(meth)acrylate; a polyfunctional acrylate or methacrylate, for example, polyethylene glycol di(meth)acrylate, trimethylolethane tri(meth)acrylate, neopentyl glycol di(meth)acrylate, pentaerythritol tri(meth)acrylate, pentaerythritol tetra(meth)acrylate, dipentaerythritol penta(meth)acrylate, dipentaerythritol hexa(meth)acrylate, hexanediol(meth)acrylate, trimethylolpropane tri(acryloyloxypropyl)ether, tri(acryloyloxyethyl)isocyanurate, a compound obtained by adding ethylene oxide or propylene oxide to a polyfunctional alcohol, for example, glycerol or trimethylolethane, followed by (meth)acrylation, an urethane(meth)acrylate as described in JP-B-48-41708, JP-B-50-6034 and JP-A-51-37193, a polyester acrylate described in JP-A-48-64183, JP-B-49-43191 and JP-B-52-30490, and an epoxy acrylate as a reaction product of an epoxy resin and (meth)acrylic acid; and a mixture thereof.

A polyfunctional (meth)acrylate obtained by reacting a polyfunctional carboxylic acid with a compound having a cyclic ether group and an ethylenically unsaturated group, for example, glycidyl(meth)acrylate is also exemplified.

Also, as other preferred radical polymerizable compounds, compounds having a fluorene ring and two or more ethylenic polymerizable groups described, for example, in JP-A-2010-160418, JP-A-2010-129825 and Japanese Patent No. 4,364,216, and a cardo resin may also be used.

Further, as other examples of the radical polymerizable compound, specific unsaturated compounds described in JP-B-46-43946, JP-B-1-40337 and JP-B-1-40336, and vinylphosphonic acid compounds described in JP-A-2-25493 can also be exemplified. In some cases, structure containing a perfluoroalkyl group described in JP-A-61-22048 can be preferably used. Moreover, photocurable monomers or oligomers described in Nippon Secchaku Kyokaishi (Journal of Japan Adhesion Society), Vol. 20, No. 7, pages 300 to 308 (1984) can also be used.

As the compound having an ethylenically unsaturated group which contains at least one addition polymerizable ethylene group and has a boiling point of 100° C. or more under normal pressure, compounds described in Paragraph Nos. [0254] to [0257] of JP-A-2008-292970 are also

In addition, radical polymerizable compounds represented by formulae (MO-1) to (MO-5) shown below can also be preferably used. In the formulae, when T is an oxyalkylene group, the oxyalkylene group is connected to R at its terminal on the carbon atom side.

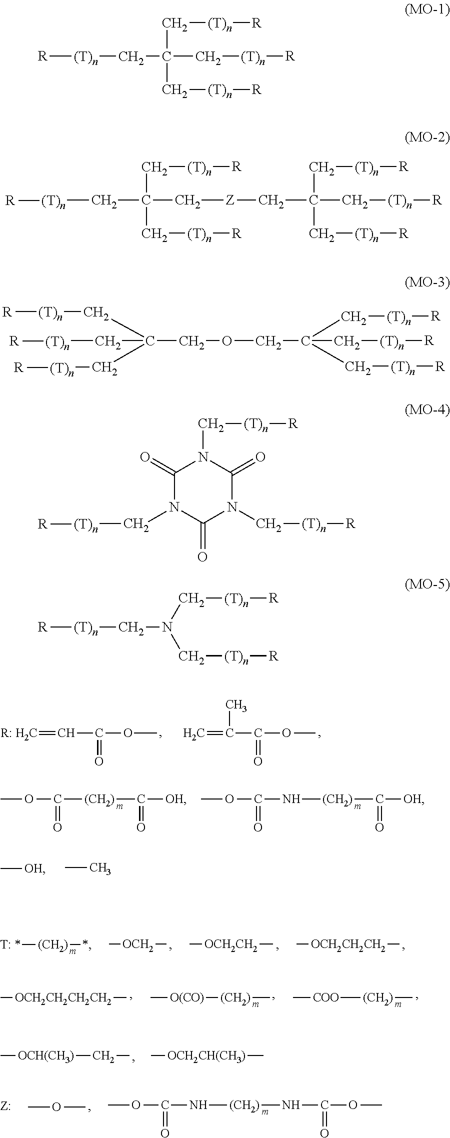

In the formulae above, n is from 0 to 14 and m is from 1 to 8. When plural Rs or plural Ts are present in one molecule, plural Rs or plural Ts may be the same or different from each other.

In each of the radical polymerizable compounds represented by formulae (MO-1) to (MO-5), at least one of plural Rs represents a group represented by —OC(═O)CH═CH₂ or —OC(═O)C(CH₃)═CH₂.

As to specific examples of the radical polymerizable compounds represented by formulae (MO-1) to (MO-5), compounds described in Paragraph Nos. [0248] to [0251] of JP-A-2007-269779 may also be preferably used in the invention.

The compound obtained by adding ethylene oxide or propylene oxide to a polyfunctional alcohol, followed by (meth)acrylation, described together with specific examples of the compounds represented by formulae (1) and (2) described in Paragraph No. [0012] of JP-A-10-62986 can also be used as the radical polymerizable compound.

Among them, dipentaerythritol triacrylate (as a commercially available product, KAYARAD D-330 produced by Nippon Kayaku Co., Ltd.), dipentaerythritol tetraacrylate (as a commercially available product, KAYARAD D-320 produced by Nippon Kayaku Co., Ltd.), dipentaerythritol penta(meth)acrylate (as a commercially available product, KAYARAD D-310 produced by Nippon Kayaku Co., Ltd.), dipentaerythritol hexa(meth)acrylate (as a commercially available product, KAYARAD DPHA produced by Nippon Kayaku Co., Ltd.), and structures where the (meth)acryloyl group of the compounds described above are connected through an ethylene glycol or propylene glycol residue are preferred as the radical polymerizable compound. Oligomer types of these compounds can also be used.

The radical polymerizable compound may be a polyfunctional monomer having an acid group, for example, a carboxyl group, sulfnic acid group or phosphoric acid group. Therefore, when the ethylenic compound has an unreacted carboxyl group as in the case of the mixture described above, it may be utilized as it is but, if desired, a non-aromatic carboxylic anhydride may be reacted with a hydroxy group of the ethylenic compound to introduce an acid group. In this case, specific examples of the non-aromatic carboxylic anhydride include tetrahydrophthalic anhydride, an alkylated tetrahydrophthalic anhydride, hexahydrophthalic anhydride, an alkylated hexahydrophthalic anhydride, succinic anhydride and maleic anhydride.

In the invention, the acid group-containing monomer is preferably a polyfunctional monomer which is an ester of an aliphatic polyhydroxy compound and an unsaturated carboxylic acid and obtained by reacting a non-aromatic carboxylic anhydride with an unreacted hydroxyl group of the aliphatic polyhydroxy compound to introduce the acid group, and particularly preferably the ester described above where the aliphatic polyhydroxy compound is pentaerythritol and/or dipentaerythritol. The commercially available product thereof includes, for example, polybasic acid-modified acryl oligomers M-510 and M-520 produced by Toagosei Co., Ltd.

The monomers may be used individually, but since it is difficult to use a single compound in view of production, two or more monomers may be used as a mixture. Also, as the monomer, a polyfunctional monomer having no acid group and a polyfunctional monomer having an acid group may be used in combination, if desired.

The acid value of the polyfunctional monomer having an acid group is preferably from 0.1 to 40 mg-KOH/g, and particularly preferably from 5 to 30 mg-KOH/g. When the acid value of the polyfunctional monomer is too low, the development dissolution characteristic decreases, whereas when the acid value of the polyfunctional monomer is too high, the production or handling thereof becomes difficult, the photopolymerization performance decreases and the curing property, for example, surface smoothness of pixel deteriorates. Therefore, in the case where two or more polyfunctional monomers having different acid groups are used in combination or in the case where a polyfunctional monomer having no acid group is used in combination, it is essential to adjust the acid value as the total polyfunctional monomer falls within the range described above.

Also, it is preferred to contain a polyfunctional monomer having a caprolactone structure as the radical polymerizable compound.

The polyfunctional monomer having a caprolactone structure is not particularly limited as long as it has a caprolactone structure in the molecule thereof and includes, for example, an ε-caprolactone-modified polyfunctional (meth)acrylate obtained by esterification of a polyhydric alcohol, for example, trimethylolethane, ditrimethylolethane, trimethylolpropane, ditrimethylolpropane, pentaerythritol, dipentaerythritol, tripentaerythritol, glycerol, diglycerol or trimethylolmelamine with (meth)acrylic acid and ε-caprolactone. Among them, a polyfunctional monomer having a caprolactone structure represented by formula (1) shown below is preferred.

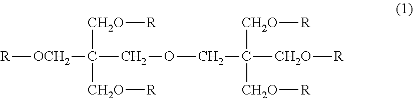

In formula (1), all of six Rs are groups represented by formula (2) shown below, or one to five of six Rs are groups represented by formula (2) shown below and the remainder is a group represented by formula (3) shown below.

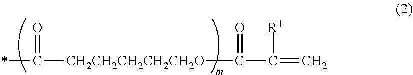

In formula (2), R¹ represents a hydrogen atom or a methyl group, m represents a number of 1 or 2, and * represents a connecting site.

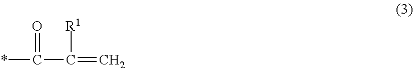

In formula (3), R¹ represents a hydrogen atom or a methyl group and * represents a connecting site.

The polyfunctional monomer having a caprolactone structure is commercially available as KAYARAD DPCA Series from Nippon Kayaku Co., Ltd. and includes DPCA-20 (compound represented by formulae (1) to (3), wherein m is 1, a number of the groups represented by formula (2) is 2, and all of R¹ are hydrogen atoms), DPCA-30 (compound represented by formulae (1) to (3), wherein m is 1, a number of the groups represented by formula (2) is 3, and all of R¹ are hydrogen atoms), DPCA-60 (compound represented by formulae (1) to (3), wherein m is 1, a number of the groups represented by formula (2) is 6, and all of R¹ are hydrogen atoms) and DPCA-120 (compound represented by formulae (1) to (3), wherein m is 2, a number of the groups represented by formula (2) is 6, and all of R¹ are hydrogen atoms).

The polyfunctional monomers having a caprolactone structure may be used individually or as a mixture of two or more thereof in the invention.

It is also preferred that the polyfunctional monomer is at least one compound selected from the group consisting of compounds represented by formulae (i) and (ii) shown below.

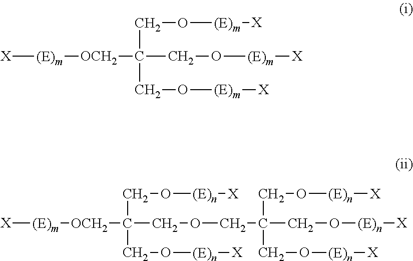

In formulae (i) and (ii), E each independently represents —((CH₂)_{y}CH₂O)— or —((CH₂)_{y}CH(CH₃)O)—, y each independently represents an integer from 0 to 10, and X each independently represents an acryloyl group, a methacryloyl group, a hydrogen atom or a carboxyl group.

In formula (i), the total number of acryloyl groups and methacryloyl groups is 3 or 4, m each independently represents an integer from 0 to 10, and the total of each m is an integer from 0 to 40, provided that when the total of each m is 0, any one of Xs is a carboxyl group.

In formula (ii), the total number of acryloyl groups and methacryloyl group is 5 or 6, n each independently represents an integer from 0 to 10, and the total of each n is an integer from 0 to 60, provided that when the total of each n is 0, any one of Xs is a carboxyl group.

In formula (i), m is preferably an integer from 0 to 6, and more preferably an integer from 0 to 4.

The total of each m is preferably an integer from 2 to 40, more preferably an integer from 2 to 16, and particularly preferably an integer from 4 to 8.

In formula (ii), n is preferably an integer from 0 to 6, and more preferably an integer from 0 to 4.

The total of each n is preferably an integer from 3 to 60, more preferably an integer from 3 to 24, and particularly preferably an integer from 6 to 12.

In a preferred embodiment, —((CH₂)_{y}CH₂O)— or —((CH₂)_{y}CH(CH₃)O)— in formula (i) or (ii) is connected to X at its terminal on the oxygen atom side.

The compounds represented by formulae (i) and (ii) may be used individually or in combination of two or more thereof. In particular, an embodiment where all of six Xs in formula (ii) are acryloyl groups is preferred.

The total content of the compound represented by formula (i) or (ii) in the radical polymerizable compound is preferably 20% by weight or more, and more preferably 50% by weight or more.

The compound represented by formula (i) or (ii) can be synthesized through a process of connecting a ring-opened skeleton of ethylene oxide or propylene oxide to pentaerythritol or dipentaerythritol by a ring-opening addition reaction, and a process of introducing a (meth)acryloyl group into the terminal hydroxyl group of the ring-opened skeleton by reacting, for example, with (meth)acryloyl chloride, which are conventionally known processes. Each of the processes is a well-known process, and the compound represented by formula (i) or (ii) can be easily synthesized by a person skilled in the art.

Of the compounds represented by formulae (i) and (ii), a pentaerythritol derivative and/or a dipentaerythritol derivative are more preferred.

Specific examples of the compounds include compounds represented by formulae (a) to (f) shown below (hereinafter, also referred to as Compounds (a) to (f) sometimes), and among them Compounds (a), (b), (e) and (f) are preferred.

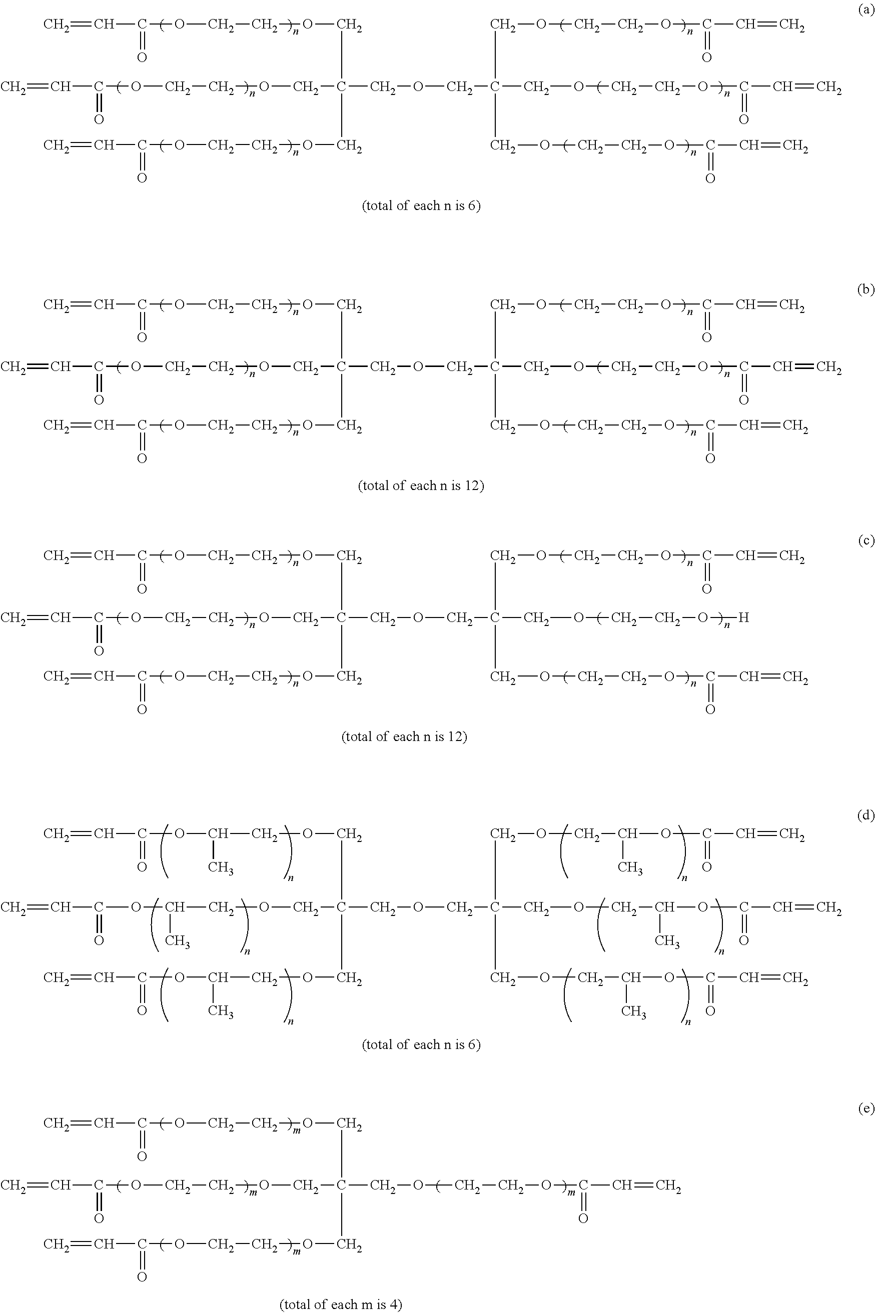

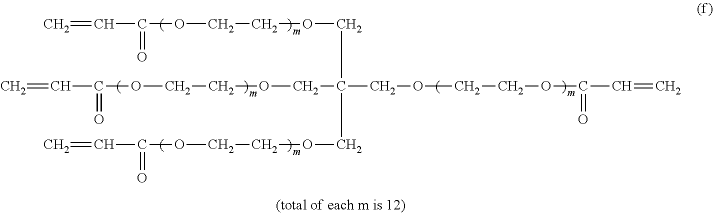

As a commercially available product of the radical polymerizable compound represented by formula (i) or (ii), for example, SR-494 which is a tetrafunctional acrylate having four ethyleneoxy chains, produced by Sartomer Co., and DPCA-60 which is a hexafunctional acrylate having six pentyleneoxy chains and TPA-330 which is a trifunctional acrylate having three isobutyleneoxy chains, produced by Nippon Kayaku Co., Ltd. are exemplified.

Further, urethane acrylates as described in JP-B-48-41708, JP-A-51-37193, JP-B-2-32293 and JP-B-2-16765, and urethane compounds having an ethylene oxide skeleton described in JP-B-58-49860, JP-B-56-17654, JP-B-62-39417 and JP-B-62-39418 are also preferred as the radical polymerizable compound. In addition, addition polymerizable compounds having an amino structure or a sulfide structure in the molecules thereof described in JP-A-63-277653, JP-A-63-260909 and JP-A-1-105238 are also used as the radical polymerizable compound.

As a commercially available product of the radical polymerizable compound, for example, Urethane Oligomer UAS-10 and UAB-140 (produced by Sanyo-Kokusaku Pulp Co., Ltd.). UA-7200 (produced by Shin-Nakamura Chemical Co., Ltd.), DPHA-40H (produced by Nippon Kayaku Co., Ltd.), and UA-306H, UA-306T, UA-3061, AH-600, T-600 and AI-600 (produced by Kyoeisha Chemical Co., Ltd.) are exemplified.

A polyfunctional thiol compound having two or more mercapto (SH) groups in its molecule is also preferably used as the radical polymerizable compound. In particular, compounds represented by formulae (I) shown below are preferred.

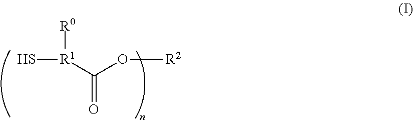

In formula (I), R¹ represents an alkylene group, R² represents an n-valent aliphatic group which may contain an atom(s) other than carbon atom, R⁰ represents an alkyl group exclusive of a hydrogen atom, and n represents an integer from 2 to 4.

Specific examples of the polyfunctional thiol compound represented by formula (I) include 1,4-bis(3-mercaptobutyryloxy)butane (represented by formula (II)), 1,3,5-tris(3-mercaptobutyloxyethyl)-1,3,5-triazine-2,4,6(1H,3H,5H)trione (represented by formula (III)) and pentaerythritol tetrakis(3-mercaptobutylate) (represented by formula (IV)). The polyfunctional thiol compounds may be used individually or in combination of two or more thereof.

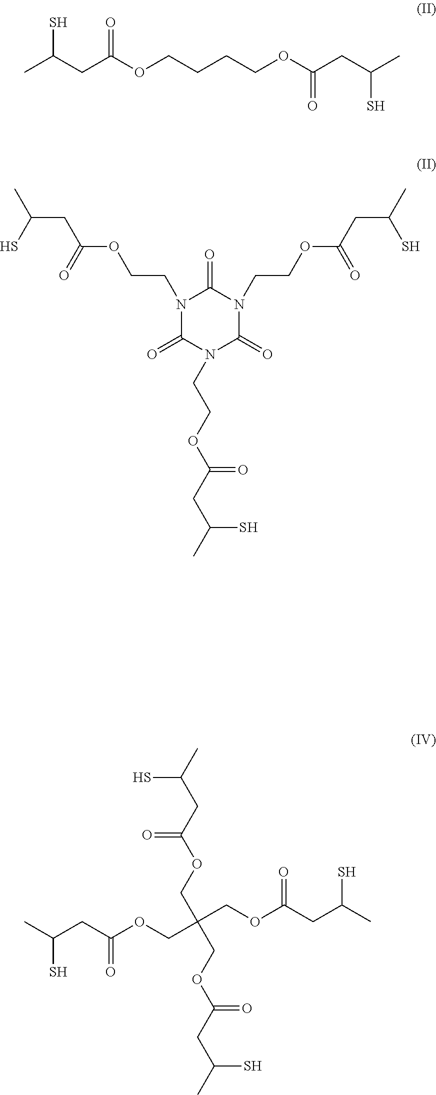

The amount of the polyfunctional thiol compound added to the temporary adhesive is preferably in a range from 0.3 to 8.9% by weight, more preferably in a range from 0.8 to 6.4% by weight, based on the total solid content exclusive of solvent of the temporary adhesive. By the addition of polyfunctional thiol compound, stability, odor, sensitivity, adhesion property and the like of the temporary adhesive can be improved.

Details of the method of using the radical polymerizable compound, for example, selection of the structure, individual or combination use, or an amount added, can be appropriately set depending on the final characteristic design of the temporary adhesive. For instance, from the standpoint of the sensitivity (efficiency of decrease in the adhesion property by the irradiation of active light or radiation), a structure having a large content of unsaturated groups per molecule is preferred, and in many cases, a difunctional or more functional compound is preferred. In order to increase the strength of adhesive layer, a trifunctional or more functional compound is preferred. A combination use of compounds different in the functional number or in the kind of polymerizable group (for example, an acrylic acid ester, a methacrylic acid ester, a styrene compound or a vinyl ether compound) is an effective method for controlling both the sensitivity and the strength. Further, a combination use of the radical polymerizable compounds of trifunctional or more functional compounds different in the length of ethylene oxide chain is also preferred. The selection and use method of the radical polymerizable compound are also important factors for the compatibility and dispersibility with other components (for example, the radical polymerizable monomer or oligomer containing a fluorine atom or a silicon atom (A) or the radical polymerization initiator (C)) contained in the temporary adhesive. For instance, the compatibility may be improved in some cases by using the radical polymerizable compound of low purity or using two or more kinds of the radical polymerizable compounds in combination. A specific structure may be selected for the purpose of improving the adhesion property to a carrier substrate.

The ionic polymerizable compound (B2) includes, for example, an epoxy compound having from 3 to 20 carbon atoms (B21) and an oxetane compound having from 4 to 20 carbon atoms (B22).

The epoxy compound having from 3 to 20 carbon atoms (B21) includes, for example, monofunctional and multifunctional epoxy compounds described below.

The monofunctional epoxy compound includes, for example, phenyl glycidyl ether, p-tert-butylphenyl glycidyl ether, butyl glycidyl ether, 2-ethylhexyl glycidyl ether, allyl glycidyl ether, 1,2-butylene oxide, 1,3-butadiene monoxide, 1,2-epoxydodecane, epichlorohydrin, 1,2-epoxydecane, styrene oxide, cyclohexene oxide, 3-methacryloyloxymethylcyclohexene oxide, 3-acryloyloxymethylcyclohexene oxide and 3-vinylcyclohexene oxide.

The multifunctional epoxy compound includes, for example, bisphenol A diglycidyl ether, bisphenol F diglycidyl ether, bisphenol S diglycidyl ether, brominated bisphenol A diglycidyl ether, brominated bisphenol F diglycidyl ether, brominated bisphenol S diglycidyl ether, epoxy novolac resin, hydrogenated bisphenol A diglycidyl ether, hydrogenated bisphenol F diglycidyl ether, hydrogenated bisphenol S diglycidyl ether, 3,4-epoxycyclohexylmethyl-3′,4′-epoxycyclohexanecarboxylate, 2-(3,4-epoxycyclohexyl-5,5-spiro-3,4-epoxy)cyclohexane-meta-dioxane, bis(3,4-epoxycyclohexylmethyl) adipate, vinylcyclohexene oxide, 4-vinyl epoxycyclohexane, bis(3,4-epoxy-6-methylcyclohexylmethyl) adipate, 3,4-epoxy-6-methylcyclohexyl-3′,4′-epoxy-6′-methylcyclohexane carboxylate, methylenebis(3,4-epoxycyclohexane), dicyclopentadiene diepoxide, ethylene glycol di(3,4-epoxycyclohexylmethyl) ether, ethylene bis(3,4-epoxycyclohexane carboxylate), dioctyl epoxy hexahydrophthalate, di-2-ethylhexyl epoxyhexahydrophthalate, 1,4-butanediol diglycidyl ether, 1,6-hexanediol diglycidyl ether, glycerol triglycidyl ether, trimethylolpropane triglycidyl ether, polyethylene glycol diglycidyl ether, polypropylene glycol diglycidyl ether, 1,1,3-tetradecadiene dioxide, limonene dioxide, 1,2,7,8-diepoxyoctane and 1,2,5,6-diepoxycyclooctane.

Of the epoxy compounds, from the standpoint of excellent polymerization speed, an aromatic epoxide and an alicyclic epoxide are preferred, and an alicyclic epoxide is particularly preferred.

The oxetane compound having from 4 to 20 carbon atoms (B22) includes, for example, compounds having from 1 to 6 oxetane rings.

The compound having one oxetane ring includes, for example, 3-ethyl-3-hydroxymethyl oxetane, 3-(meth)allyloxymethyl-3-ethyl oxetane, (3-ethyl-3-oxetanylmethoxy)methylbenzene, 4-fluoro-[1-(3-ethyl-3-oxetanylmethoxy)methyl]benzene, 4-methoxy[1-(3-ethyl-3-oxetanylmethoxy)methyl]benzene, [1-(3-ethyl-3-oxetanylmethoxy)ethyl]phenyl ether, isobutoxymethyl(3-ethyl-3-oxetanylmethyl)ether, isobornyloxyethyl(3-ethyl-3-oxetanylmethyl)ether, isobornyl(3-ethyl-3-oxetanylmethyl)ether, 2-ethylhexyl(3-ethyl-3-oxetanylmethyl)ether, ethyl diethylene glycol(3-ethyl-3-oxetanylmethyl)ether, dicyclopentenyl(3-ethyl-3-oxetanylmethyl)ether, tetrahydrofurfuryl(3-ethyl-3-oxetanylmethyl) ether, tetrabromophenyl(3-ethyl-3-oxetanylmethyl)ether, 2-tetrabromophenoxyethyl(3-ethyl-3-oxetanylmethyl)ether, tribromophenyl(3-ethyl-3-oxetanylmethyl)ether, 2-tribromophenoxyethyl(3-ethyl-3-oxetanylmethyl)ether, 2-hydroxyethyl(3-ethyl-3-oxetanylmethyl)ether, 2-hydroxypropyl(3-ethyl-3-oxetanylmethyl)ether, butoxyethyl(3-ethyl-3-oxetanylmethyl)ether, pentachlorophenyl(3-ethyl-3-oxetanylmethyl)ether, pentabromophenyl(3-ethyl-3-oxetanylmethyl)ether and bornyl(3-ethyl-3-oxetanylmethyl)ether.

The compound having from 2 to 6 oxetane rings includes, for example, 3,7-bis(3-oxetanyl)-5-oxanonane, 3,3′-(1,3-(2-methylenyl)propanediylbis(oxymethylene))bis(3-ethyloxetane), 1,4-bis[(3-ethyl-3-oxetanylmethoxy)methyl]benzene, 1,2-bis[(3-ethyl-3-oxetanylmethoxy)methyl]ethane, 1,3-bis[(3-ethyl-3-oxetanylmethoxy)methyl]propane, ethylene glycol bis(3-ethyl-3-oxetanylmethyl)ether, dicyclopentenyl bis(3-ethyl-3-oxetanylmethyl)ether, triethylene glycol bis(3-ethyl-3-oxetanylmethyl)ether, tetraethylene glycol bis(3-ethyl-3-oxetanylmethyl)ether, tricyclodecanediyldimethylene(3-ethyl-3-oxetanylmethyl) ether, trimethylol propane tris(3-ethyl-3-oxetanylmethyl)ether, 1,4-bis(3-ethyl-3-oxetanylmethoxy)butane, 1,6-bis(3-ethyl-3-oxetanylmethoxy)hexane, pentaerythritol tris(3-ethyl-3-oxetanylmethyl)ether, pentaerythritol tetrakis(3-ethyl-3-oxetanylmethyl)ether, polyethylene glycol bis(3-ethyl-3-oxetanylmethyl)ether, dipentaerythritol hexakis(3-ethyl-3-oxetanylmethyl)ether, dipentaerythritol pentakis(3-ethyl-3-oxetanylmethyl)ether, dipentaerythritol tetrakis(3-ethyl-3-oxetanylmethyl) ether, caprolactone-modified dipentaerythritol hexakis(3-ethyl-3-oxetanylmethyl)ether, caprolactone-modified dipentaerythritol pentakis(3-ethyl-3-oxetanylmethyl)ether, ditrimethylolpropane tetrakis(3-ethyl-3-oxetanylmethyl)ether, EO-modified bisphenol A bis(3-ethyl-3-oxetanylmethyl)ether, PO-modified bisphenol A bis(3-ethyl-3-oxetanylmethyl) ether, EO-modified hydrogenated bisphenol A bis(3-ethyl-3-oxetanylmethyl)ether, PO-modified hydrogenated bisphenol A bis(3-ethyl-3-oxetanylmethyl)ether and EO-modified bisphenol F (3-ethyl-3-oxetanylmethyl)ether.

The content of the other radical polymerizable monomer or oligomer is preferably from 30 to 90% by weight, more preferably from 40 to 90% by weight, still more preferably from 50 to 85% by weight, based on the total solid content of the temporary adhesive from the standpoint of good adhesion strength and good releasing property.

Also, a ratio (weight ratio) of contents of the other radical polymerizable monomer or oligomer and the polymer compound (B) is preferably from 90/10 to 10/90, and more preferably from 85/15 to 40/60.

### <Other Components>

### [Acid Generator]

The temporary adhesive according to the invention may contain a compound which generates an acid by irradiation of actinic light or radiation or heating (hereinafter, also simply referred to as an “acid generator”).

Of the compounds which generate an acid by irradiation of actinic light or radiation, a compound which generates an acid having pKa of 4 or less is preferred, and a compound which generates an acid having pKa of 3 or less is more preferred.

Examples of the compound which generates an acid include a trichloromethyl-s-triazine, a sulfonium salt, an iodonium salt, a quaternary ammonium salt, a diazomethane compound, an imidosulfonate compound and an oximesulfonate compound. Of the compounds, from the standpoint of high sensitivity, an oximesulfonate compound is preferably used. The acid generators may be used individually or in combination of two or more thereof.

The acid generator specifically includes, acid generators described in Paragraph Nos. [0073] to [0095] of JP-A-2012-8223.

The content of the compound which generates a radical or an acid by irradiation of active light or radiation according to the invention (total content in the case of using two or more compounds) is preferably from 0.1 to 50% by weight, more preferably from 0.1 to 30% by weight, still more preferably from 0.1 to 20% by weight, based on the total solid content of the temporary adhesive.

As the compound which generates an acid by heat (hereinafter, also simply referred to as a “heat acid generator”), known heat acid generators can be used.

The heat acid generator is a compound having preferably a heat decomposition point ranging from 130 to 250° C., and more preferably from 150 to 220° C.

The heat acid generator includes, for example, a compound which generates an acid of low nucleophilicity, for example, a sulfonic acid, a carboxylic acid or a disulfonyl imide.

An acid generated from the heat acid generator includes preferably a sulfonic acid, an alkyl or aryl carboxylic acid substituted with an electron-withdrawing group and a disulfonyl imide substituted with an electron-withdrawing group, each of which has strong pKa of 2 or less. Examples of the electron-withdrawing group include a halogen atom, for example, a fluorine atom, a haloalkyl group, for example, a trifluoromethyl group, a nitro group and a cyano group.

As the heat acid generator, a photo acid generator which generates an acid by irradiation of active light or radiation described above can be applied. For instance, an onium salt, for example, a sulfonium salt or an iodonium salt, an N-hydroxyimidosulfonate compound, an oxime sulfonate and an o-nitrobenzyl sulfonate are exemplified.

In the invention, it is also preferred to use a sulfonic acid ester which substantially does not generate an acid by the irradiation of active light or radiation but generates an acid by heat.

To not substantially generate an acid by the irradiation of active light or radiation can be judged by measuring an infrared absorption (IR) spectrum or a nuclear magnetic resonance (NMR) spectrum before and after exposure of the compound and confirming that there is no change in the spectrum.

The molecular weight of the sulfonic acid ester is preferably from 230 to 1,000, and more preferably from 230 to 800.

The sulfonic acid ester which can be used in the invention may be a commercially available product or a sulfonic acid ester synthesized by a known method. The sulfonic acid ester can be synthesized, for example, by reacting a sulfonyl chloride or a sulfonic anhydride with a corresponding polyhydric alcohol under a basic condition.

The heat acid generators may be used individually or in combination of two or more thereof.

The content of the acid generator in the temporary adhesive according to the invention is preferably from 0.01 to 50% by weight, more preferably from 0.1 to 20% by weight, most preferably from 0.5 to 10% by weight, based on the total solid content of the adhesive composition, from the standpoint of reducing the adhesion property of the adhesive layer in the case of conducting the irradiation of heat before performing the temporary adhesion of the member to be processed and the adhesive support and increasing the adhesion property of the adhesive layer in the case of conducting the irradiation of heat after performing the temporary adhesion of the member to be processed and the adhesive support.

### [Chain Transfer Agent]

The temporary adhesive according to the invention preferably contains also a chain transfer agent. The chain transfer agent is defined, for example, in Kobunshi Jiten (Polymer Dictionary), Third Edition, pages 683 to 684, edited by The Society of Polymer Science, Japan (2005). As the chain transfer agent, for example, compounds having SH, PH, SiH or GeH in their molecules are used. The compound donates a hydrogen to a low active radical species to generate a radical or is oxidized and then deprotonated to generate a radical. In the temporary adhesive, a thiol compound (for example, a 2-mercaptobenzimidazole, a 2-mercaptobenzothiazole, a 2-mercaptobenzoxazole, a 3-mercaptotriazole or a 5-mercaptotetrazole) is preferably used.

The content of the chain transfer agent is preferably from 0.01 to 20 parts by weight, more preferably from 1 to 10 parts by weight, particularly preferably from 1 to 5 parts by weight, per 100 parts by weight of the total solid content of the temporary adhesive.

### [Polymerization Inhibitor]

To the temporary adhesive according to the invention is preferably added a small amount of a polymerization inhibitor in order to prevent undesired thermal polymerization of the radical polymerizable monomer during the production or preservation of the temporary adhesive.

As the polymerization inhibitor, for example, hydroquinone, p-methoxyphenol, di-tert-butyl-p-cresol, pyrogallol, tert-butylcatechol, benzoquinone 4,4′-thiobis(3-methyl-6-tert-butylphenol), 2,2′-methylenebis(4-methyl-6-tert-butylphenol) and N-nitroso-N-phenylhydroxylamine aluminum salt are preferably exemplified.

The addition amount of the polymerization inhibitor is preferably from about 0.01 to about 5% by weight based on the total solid content of the temporary adhesive.

### [Higher Fatty Acid Derivative or the Like]

In order to prevent polymerization inhibition due to oxygen, a higher fatty acid derivative or the like, for example, behenic acid or behenic acid amide may be added to the temporary adhesive according to the invention to localize on the surface of the adhesive layer in the process of drying after the coating. The addition amount of the higher fatty acid derivative is preferably from about 0.1 to about 10% by weight based on the total solid content of the temporary adhesive.

### [Other Additives]

Also, the temporary adhesive according to the invention may contain, if desired, various additives, for example, a curing agent, a curing catalyst, a silane coupling agent, a filler, an adherence accelerator, an antioxidant, an ultraviolet absorber or an aggregation inhibitor as long as the effects of the invention are not impaired.

### [Solvent]

The temporary adhesive for production of semiconductor device according to the invention may be coated by dissolving it in a solvent (ordinarily, an organic solvent). The solvent is basically not particularly limited as long as it satisfies solubility of each of the components and coating property of the temporary adhesive.

The organic solvent preferably includes, an ester, for example, ethyl acetate, n-butyl acetate, isobutyl acetate, amyl formate, isoamyl acetate, isobutyl acetate, butyl propionate, isopropyl butyrate, ethyl butyrate, butyl butyrate, methyl lactate, ethyl lactate, an alkyl oxyacetate (for example, methyl oxyacetate, ethyl oxyacetate, butyl oxyacetate, methyl methoxyacetate, ethyl methoxyacetate, butyl methoxyacetate, methyl ethoxyacetate or ethyl ethoxyacetate), an alkyl 3-oxypropionate (for example, methyl 3-oxypropionate, ethyl 3-oxypropionate, methyl 3-methoxypropionate, ethyl 3-methoxypropionate, methyl 3-ethoxypropionate or ethyl 3-ethoxypropionate), an alkyl 2-oxypropionate (for example, methyl 2-oxypropionate, ethyl 2-oxypropionate, propyl 2-oxypropionate, methyl 2-methoxypropionate, ethyl 2-methoxypropionate, propyl 2-methoxypropionate, methyl 2-ethoxypropionate or ethyl 2-ethoxypropionate), methyl 2-oxy-2-methylpropionate, ethyl 2-oxy-2-methylpropionate, methyl 2-methoxy-2-methylpropionate, ethyl 2-ethoxy-2-methylpropionate, methyl pyruvate, ethyl pyruvate, propyl pyruvate, methyl acetoacetate, ethyl acetoacetate, methyl 2-oxobutanoate or ethyl 2-oxobutanoate; an ether, for example, diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol monomethyl ether acetate (PGMEA), propylene glycol monoethyl ether acetate or propylene glycol monopropyl ether acetate; a ketone, for example, methyl ethyl ketone (2-butanone), cyclohexanone, 2-heptanone, 3-heptanone or methyl amyl ketone; an aromatic hydrocarbon, for example, toluene or xylene; and other organic solvent, for example, N-methyl-2-pyrrolidone or limonene.

From the standpoint of improving the coated surface state and the like, the solvents are also preferably used in the state of mixing two or more thereof. In this case, a mixed solution composed of two or more solvents selected from methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether and propylene glycol methyl ether acetate is particularly preferred.

The solvent is preferably N-methyl-2-pyrrolidone, 2-butanone, methyl amyl ketone, limonene or propylene glycol monomethyl ether acetate (PGMEA).

The content of the solvent in the coating solution of the temporary adhesive is set such that the total solid content concentration of the temporary adhesive becomes preferably from 5 to 80% by weight, more preferably from 5 to 70% by weight, still more preferably from 5 to 60% by weight, particularly preferably from 10 to 60% by weight, from the standpoint of coating property.

### [Surfactant]

To the temporary adhesive according to the invention may be added various surfactants from the standpoint of more increasing the coating property. As the surfactant, various surfactants, for example, a fluorine-based surfactant, a nonionic surfactant, a cationic surfactant, an anionic surfactant or a silicone-based surfactant can be used.

In particular, by containing a fluorine-based surfactant in the temporary adhesive according to the invention, the liquid characteristic (particularly, fluidity) of a coating solution prepared is more increased so that the uniformity of coating thickness or the liquid-saving property can be more improved.

Specifically, in the case of forming a film by using a coating solution to which the temporary adhesive containing a fluorine-based surfactant is applied, the interface tension between a surface to be coated and the coating solution is reduced, whereby wettability to the surface to be coated is improved and the coating property on the surface to be coated is increased. This is effective in that even when a thin film of about several μm is formed using a small liquid volume, formation of the film having a little thickness unevenness and a uniform thickness can be performed in a preferable manner.

The fluorine content in the fluorine-based surfactant is preferably from 3 to 40% by weight, more preferably from 5 to 30% by weight, and particularly preferably from 7 to 25% by weight. The fluorine-based surfactant having a fluorine content in the range described above is effective in view of the uniformity of coating thickness and the liquid-saving property and also exhibits good solubility in the temporary adhesive.

Examples of the fluorine-based surfactant include MEGAFAC F171, MEGAFAC F172. MEGAFAC F173, MEGAFAC F176, MEGAFAC F177, MEGAFAC F141, MEGAFAC F142, MEGAFAC F143, MEGAFAC F144, MEGAFAC R30, MEGAFAC F437, MEGAFAC F475, MEGAFAC F479, MEGAFAC F482, MEGAFAC F554. MEGAFAC F780 and MEGAFAC F781 (produced by DIC Corp.), FLUORAD FC430, FLUORAD FC431 and FLUORAD FC171 (produced by Sumitomo 3M Ltd.), SURFLON S-382, SURFLON SC-101, SURFLON SC-103, SURFLON SC-104, SURFLON SC-105, SURFLON SC-1068, SURFLON SC-381, SURFLON SC-383, SURFLON S393 and SURFLON KH-40 (produced by Asahi Glass Co., Ltd.), and PF636, PF656, PF6320, PF6520 and PF7002 (produced by OMNOVA Solutions Inc.).

Specific examples of the nonionic surfactant include glycerol, trimethylolpropane, trimethylolethane, their ethoxylate and propoxylate (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, and a sorbitan fatty acid ester (PLURONIC L10, L31, L61, L62, 10R5, 17R2 and 25R2 and TETRONIC 304, 701, 704, 901, 904 and 150R1 (produced by BASF Corp.) and SOLSPERSE 20000 (produced by The Lubrizol Corp.)).

Specific examples of the cationic surfactant include a phthalocyanine derivative (EFKA-745, produced by Morishita Sangyo K. K.), an organosiloxane polymer (KP341, produced by Shin-Etsu Chemical Co., Ltd.), a (meth)acrylic acid (co)polymer (POLYFLOW No. 75, No. 90 and No. 95 (produced by Kyoeisha Chemical Co., Ltd.) and W001 (produced by Yusho Co., Ltd.).

Specific examples of the anionic surfactant include W004, W005 and W017 (produced by Yusho Co., Ltd.).

Examples of the silicone-based surfactant include TORAY SILICONE DC3PA, TORAY SILICONE SH7PA, TORAY SILICONE DC11PA. TORAY SILICONE SH21PA, TORAY SILICONE SH28PA, TORAY SILICONE SH29PA, TORAY SILICONE SH30PA and TORAY SILICONE SH8400 (produced by Dow Corning Toray Co., Ltd.), TSF-4440, TSF-4300, TSF-4445, TSF-4460 and TSF-4452 (produced by Momentive Performance Materials Inc.), KP341, KF6001 and KF6002 (produced by Shin-Etsu Silicone Co., Ltd.), and BYK307. BYK323 and BYK330 (produced by BYK-Chemie GmbH).

The surfactants may be used only one kind or in combination of two or more kinds thereof.

The addition amount of the surfactant is preferably from 0.001 to 2.0% by weight, more preferably from 0.005 to 1.0% by weight, based on the total solid content of the temporary adhesive.

Next, the adhesive support and the production method of semiconductor device using the temporary adhesive for production of semiconductor device according to the invention described above will be described.

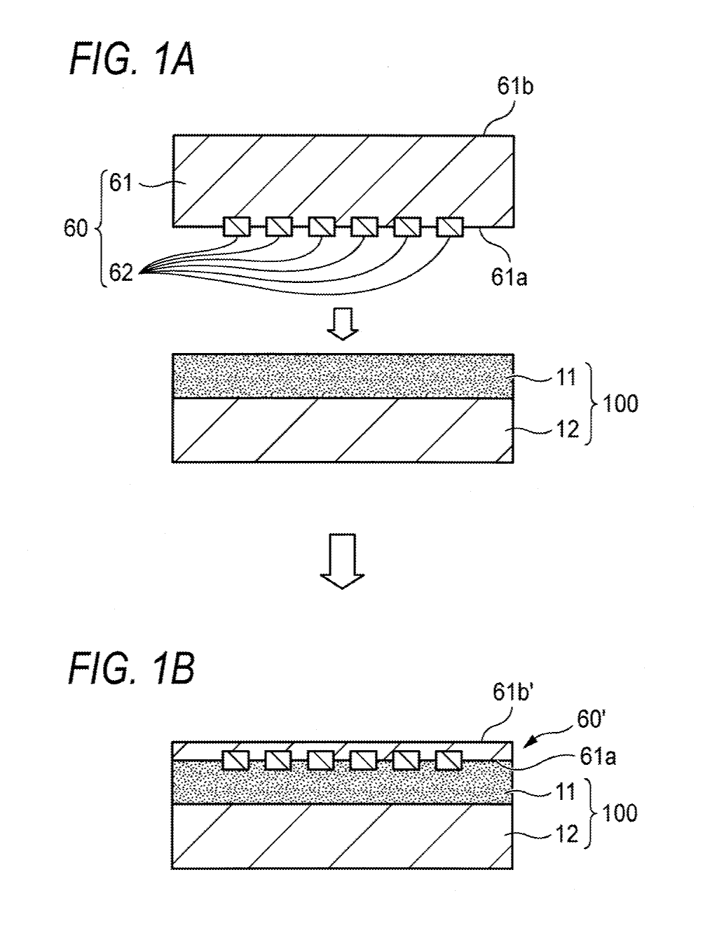

FIG. 1A and FIG. 1B are a schematic cross-sectional view illustrating temporary adhesion of an adhesive support and a device wafer and a schematic cross-sectional view showing a state in which the device wafer temporarily adhered by the adhesive support is thinned, respectively.

According to an embodiment of the invention, first, an adhesive support 100 having an adhesive layer 11 provided on a carrier substrate 12 is prepared as shown in FIG. 1A.

A material of the carrier substrate 12 is not particularly limited and includes, for example, a silicon substrate, a glass substrate and a metal substrate. Taking them into consideration that a silicon substrate which is typically used as a substrate of semiconductor device is hardly contaminated and that an electrostatic chuck which is commonly used in the process of producing a semiconductor device can be used, a silicon substrate is preferred.

The thickness of the carrier substrate 12 is, for example, in a range from 300 μm to 5 mm, and it is not particularly limited.

The adhesive layer 11 can be formed by coating the temporary adhesive for production of semiconductor device according to the invention on the carrier substrate 12 by using a conventionally known method, for example, a spin coating method, a spraying method, a roller coating method, a flow coating method, a doctor coating method or a dipping method, followed by drying.

The thickness of the adhesive layer 11 is, for example, in a range from 1 to 500 μm, and it is not particularly limited.

Then, temporary adhesion of the adhesive support obtained as above and a device wafer, thinning of the device wafer and release of the device wafer from the adhesive support will be described in detail.

As shown in FIG. 1A, the device wafer 60 (member to be processed) has a plurality of device chips 62 provided on a surface 61a of silicon substrate 61.

The thickness of the silicon substrate 61 is, for example, in a range from 200 to 1,200 μm.

The surface 61a of silicon substrate 61 is pressed against the adhesive layer 11 of the adhesive support 100. Thus, the surface 61a of silicon substrate 61 and the adhesive layer 11 are adhered, whereby the adhesive support 100 and the device wafer 60 are temporarily adhered.

The electric resistance value of the adhesive layer 11 is preferably 4Ω or more in order not to apply an electrical stimulus to a device chip 62.

Also, after that, if desired, the adhesion body composed of the adhesive support 100 and the device wafer 60 may be heated (subjected to irradiation of heat), thereby making the adhesive layer more tough. Thus, since not only the anchor effect at the interface between the adhesive support and the member to be processed is accelerated but also the cohesion failure of the adhesive layer, which may likely occur when the device wafer 60 is subjected to a mechanical or chemical processing described below, can be prevented, the adhesion property of the adhesive support 100 is increased.

The heating temperature is preferably from 50 to 300° C., more preferably from 100 to 250° C., and still more preferably from 150 to 220° C.

The heating time is preferably from 20 seconds to 10 minutes, more preferably from 30 seconds to 5 minutes, and still more preferably from 40 seconds to 3 minutes.

Then, a rear surface 61b of the silicon substrate 61 is subjected to a mechanical or chemical processing, specifically, a thinning processing, for example, grinding or chemical mechanical polishing (CMP) to reduce the thickness (for example, thickness of 1 to 200 μm) of the silicon substrate 61, thereby obtaining a thin device wafer 60′ as shown in FIG. 1B.

Also, as the mechanical or chemical processing, after the thinning processing a processing of forming a through hole (not shown) passing through the silicon substrate from the rear surface 61b′ of the thin device wafer 60′ and forming a though-silicon electrode (not shown) in the through hole may be performed, if desired.

Then, the surface 61a of the thin device wafer 60′ is released from the adhesive layer 11 of the adhesive support 100.

A method for the release is not particularly limited, and it is preferably performed by bringing the adhesive layer 11 into contact with a release solution and then, if desired, sliding the thin device wafer 60′ to the adhesive support 100 or stripping the thin device wafer 60′ from the adhesive support 100. Since the temporary adhesive according to the invention has a high affinity to the release solution, the temporary adhesion between the adhesive layer 11 and the surface 61a of the thin device wafer 60′ can be easily released by means of the method described above.

Also, the method for the release may be mechanical release.

After releasing the thin device wafer 60′ from the adhesive support 100, if desired, the thin device wafer 60′ is subjected to various known processings, thereby producing a semiconductor device having the thin device water 60′.

### <Release Solution>

The release solution is described in detail below.

As the release solution, water and the solvent (organic solvent) described above can be used. Further, as the release solution, an organic solvent, for example, 2-heptanone, limonene, acetone or p-menthane is also preferred and, in particular, in the case where the device wafer is a device wafer with a protective layer described hereinafter, the release solution is preferably limonene or p-menthane and more preferably limonene. Thus, the protective layer is easily dissolved in the release solution so that the releasing property is further increased.

Moreover, from the standpoint of the releasing property, the release solution may contain an alkali, an acid or a surfactant. Furthermore, from the standpoint of the releasing property, an embodiment of mixing two or more kinds of the organic solvents and water or an embodiment of mixing two or more kinds the alkalis, acids and surfactants is preferred.

As the alkali, an inorganic alkali agent, for example, sodium tertiary phosphate, potassium tertiary phosphate, ammonium tertiary phosphate, sodium secondary phosphate, potassium secondary phosphate, ammonium secondary phosphate, sodium carbonate, potassium carbonate, ammonium carbonate, sodium hydrogen carbonate, potassium hydrogen carbonate, ammonium hydrogen carbonate, sodium borate, potassium borate, ammonium borate, sodium hydroxide, ammonium hydroxide, potassium hydroxide or lithium hydroxide, or an organic alkali agent, for example, monomethylamine, dimethylamine, trimethylamine, monoethylamine, diethylamine, triethylamine, monoisopropylamine, diisopropylamine, triisopropylamine, n-butylamine, monoethanolamine, diethanolamine, triethanolamine, monoisopropanolamine, diisopropanolamine, ethyleneimine, ethylenediamine, pyridine or tetramethylammonium hydroxide can be used. The alkali agents can be used individually or in combination of two or more thereof.

As the acid, an inorganic acid, for example, a hydrogen halide, sulfuric acid, nitric acid, phosphoric acid or boric acid, or an organic acid, for example, methanesulfonic acid, ethanesulfonic acid, benzenesulfonic acid, p-toluenesulfonic acid trifluoromethanesulfonic acid, acetic acid, citric acid, formic acid, gluconic acid, lactic acid, oxalic acid or tartaric acid can be used.

As the surfactant, an anionic, cationic, nonionic or amphoteric surfactant can be used. In this case, the content of the surfactant is preferably from 1 to 20% by weight, more preferably from 1 to 10% by weight, based on the total amount of the release solution.

By controlling the content of the surfactant to the range described above, the releasing property of the thin device wafer 60′ from the adhesive support 100 tends to be more improved.

The anionic surfactant is not particularly limited, and includes, for example, fatty acid salts, abietic acid salts, hydroxyalkanesulfonic acid salts, alkanesulfonic acid salts, dialkylsulfosuccinic acid salts, straight-chain alkylbenzenesulfonic acid salts, branched alkylbenzenesulfonic acid salts, alkylnaphthalenesulfonic acid salts, alkyldiphenylether (di)sulfonic acid salts, alkylphenoxy polyoxyethylene alkylsulfonic acid salts, polyoxyethylene alkylsulfophenyl ether salts, N-alkyl-N-oleyltaurine sodium salt, N-alkylsulfosuccinic acid monoamide disodium salts, petroleum sulfonic acid salts, sulfated castor oil, sulfated beef tallow oil, sulfate ester slats of fatty acid alkyl ester, alkyl sulfate ester salts, polyoxyethylene alkyl ether sulfate ester salts, fatty acid monoglyceride sulfate ester salts, polyoxyethylene alkyl phenyl ether sulfate ester salts, polyoxyethylene styryl phenyl ether sulfate ester salts, alkyl phosphate ester salts, polyoxyethylene alkyl ether phosphate ester salts, polyoxyethylene alkyl phenyl ether phosphate ester salts, partially saponified products of styrene-maleic anhydride copolymer, partially saponified products of olefin-maleic anhydride copolymer and naphthalene sulfonate formalin condensates. Of the compounds, alkylbenzensulfonic acid salts, alkylnaphthalenesulfonic acid salts and alkyldiphenylether (di)sulfonic acid salts are particularly preferably used.

The cationic surfactant is not particularly limited and conventionally known cationic surfactants can be used. Examples of the cationic surfactant include alkylamine salts, quaternary ammonium salts, alkylimidazolinium salts, polyoxyethylene alkyl amine salts and polyethylene polyamine derivatives.

The nonionic surfactant is not particularly limited and includes, for example, polyethylene glycol type higher alcohol ethylene oxide adducts, alkylphenol ethylene oxide adducts, alkylnaphthol ethylene oxide adducts, phenol ethylene oxide adducts, naphthol ethylene oxide adducts, fatty acid ethylene oxide adducts, polyhydric alcohol fatty acid ester ethylene oxide adducts, higher alkylamine ethylene oxide adducts, fatty acid amide ethylene oxide adducts, ethylene oxide addacts of fat, polypropylene glycol ethylene oxide adducts, dimethylsiloxane-ethylene oxide block copolymers, dimethylsiloxane-(propylene oxide-ethylene oxide) block copolymers, fatty acid esters of polyhydric alcohol type glycerol, fatty acid esters of pentaerythritol, fatty acid esters of sorbitol and sorbitan, fatty acid esters of sucrose, alkyl ethers of polyhydric alcohols and fatty acid amides of alkanolamines. Of the compounds, those having an aromatic ring and an ethylene oxide chain are preferred and alkyl-substituted or unsubstituted phenol ethylene oxide adducts and alkyl-substituted or unsubstituted naphthol ethylene oxide adducts are more preferred.

The amphoteric surfactant is not particularly limited and includes, for example, amine oxide type, for example, alkyldimethylamine oxide, betaine type, for example, alkyl betaine, and amino acid type, for example, sodium salt of alkylamino fatty acid. In particular, alkyldimethylamine oxide which may have a substituent, alkyl carboxyl betaine which may have a substituent and alkyl sulfo betaine which may have a substituent are preferably used. Specifically, compounds represented by formula (2) described in Paragraph No. [0256] of JP-A-2008-203359, compounds represented by formulae (I), (II) and (VI) described in Paragraph No. [0028] of JP-A-2008-276166 and compounds described in Paragraph Nos. [0022] to [0029] of JP-A-2009-47927 can be used.

The release solution can further contain an additive, for example, a defoaming agent or a water softener, if desired.

Now, a conventional embodiment is described.

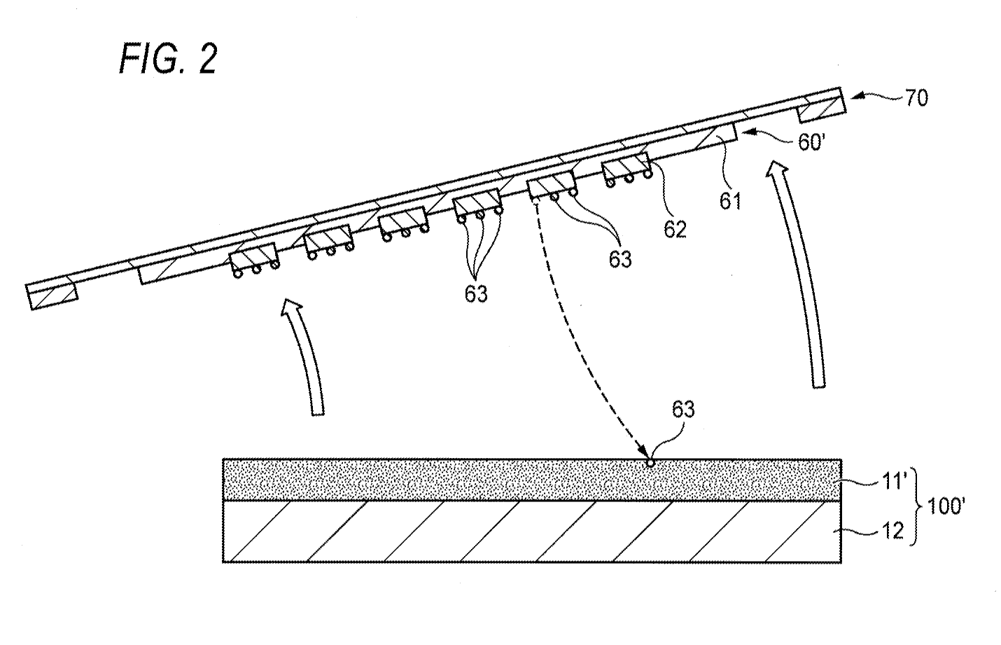

FIG. 2 is a schematic cross-sectional view illustrating release of a temporary adhering state between a conventional adhesive support and a device wafer.

In the conventional embodiment, as shown in FIG. 2, except for using as the adhesive support, an adhesive support 100′ having an adhesive layer 11′ formed from a conventional temporary adhesive provided on a carrier substrate 12, the temporary adhesion of the adhesive support 100′ to a device wafer and the thinning processing of the silicon substrate in the device wafer are performed by the same procedures as described with reference to FIG. 1A and FIG. 1B, and then a thin device wafer 60′ is released from the adhesive support 100′ by the same procedure as described above.

However, according to the conventional temporary adhesive it is difficult to temporarily support a member to be processed with a high adhesive force and to easily release the temporary support for the member processed without imparting damage to the member processed. For example, when a temporary adhesive having a high adhesion property of the conventional temporary adhesives is adopted in order to perform sufficiently temporary adhesion between a device wafer and a carrier substrate, the temporary adhesion between the device wafer and the carrier substrate tends to become too strong. Thus, for example, as shown in FIG. 2, in the case where a tape (for example, a dicing tape) 70 is adhered on a rear surface 61b′ of a thin device wafer 60′ and the thin device wafer 60′ is released from the adhesive support 100′ for the purpose of releasing such a strong temporary adhesion, an inconvenience is apt to occur in that a device chip 62 is damaged, for example, a bump 63 is released from the device chip 62 having the bump 63 provided thereon.

On the other hand, when a temporary adhesive having a low adhesion property of the conventional temporary adhesives is adopted, although the temporary support for the member processed can be easily released, the temporary adhesion between a device wafer and a carrier substrate is originally too weak so that an inconvenience is apt to occur in that the device wafer cannot be firmly supported by the carrier substrate.

However, the adhesive layer formed from the temporary adhesive according to the invention exhibits a sufficient adhesion property, and the temporary adhesion between the device wafer 60 and the adhesive support 100 can be easily released particularly by bringing the adhesive layer 11 into contact with the release solution. Specifically, due to the temporary adhesive according to the invention, the device wafer 60 can be temporarily supported with a high adhesive force and the temporary support for the thin device wafer 60′ can be easily released without imparting damage to the thin device wafer 60′.

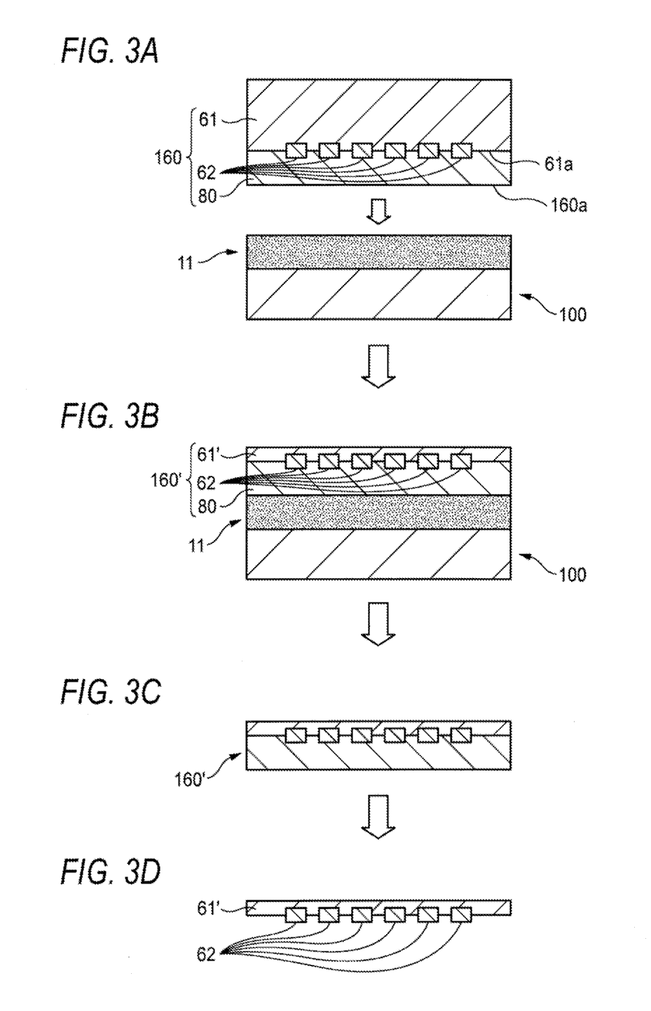

FIG. 3A, FIG. 3B, FIG. 3C and FIG. 3D are a schematic cross-sectional view illustrating temporary adhesion of an adhesive support and a device wafer provided with a protective layer, a schematic cross-sectional view showing a state in which the device wafer provided with a protective layer temporarily adhered by the adhesive support is thinned, a schematic cross-sectional view showing the thin device wafer provided with a protective layer released from the adhesive support and a schematic cross-sectional view showing the thin device wafer, respectively.

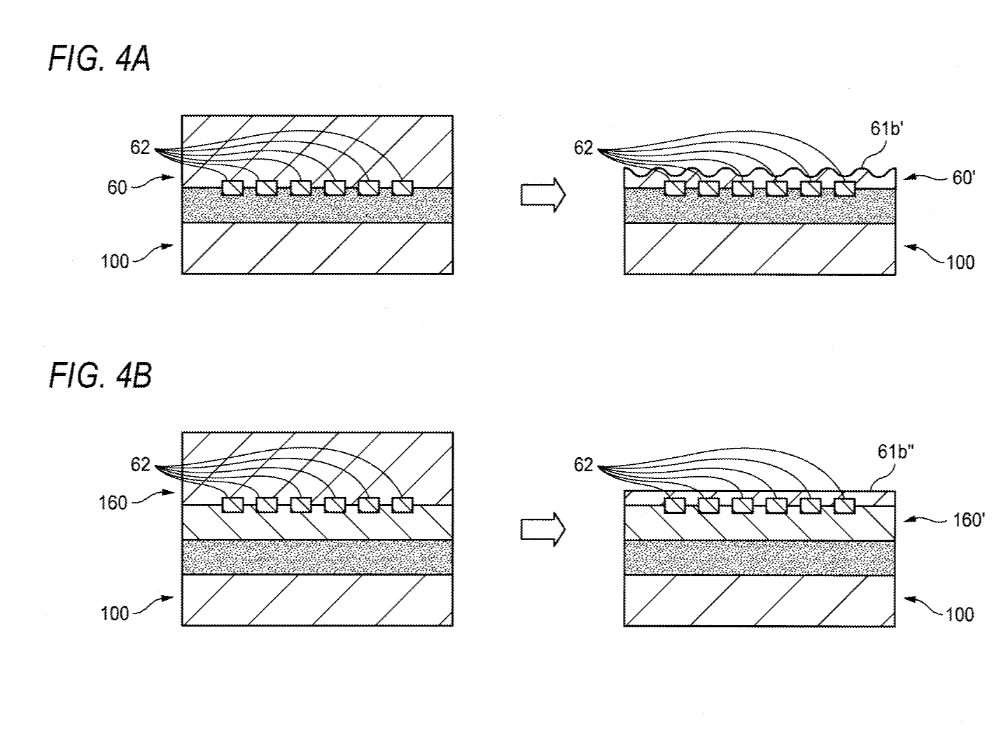

FIG. 4A and FIG. 4B are a schematic cross-sectional view illustrating a state in which the device wafer temporarily adhered by the adhesive support is thinned and a schematic cross-sectional view illustrating a state in which the device wafer provided with a protective layer temporarily adhered by the adhesive support is thinned, respectively.

According to the first embodiment of the invention described above, a device wafer with a protective layer 160 (member to be processed) may be used in place of the device wafer 60, as shown in FIG. 3A.

The device wafer with a protective layer 160 is composed of a silicon substrate 61 having a plurality of device chips 62 provided on a surface 61a thereof (member to be processed) and a protective layer 80 for protecting the device chips 62 provided on the surface 61a of the silicon substrate 61.

The thickness of the protective layer 80 is, for example, in a range from 1 to 1,000 μm.

As the protective layer 80, known protective layers can be used without limitation, and the protective layer which can certainly protect the device chips 62 is preferred.

As a material constituting the protective layer 80 (compound for protective layer), a known compound for the purpose of protecting the member to be processed can be used without limitation. Specifically, a synthetic resin, for example, a phenol resin, an epoxy resin, a melamine resin, a urea resin, an unsaturated polyester resin, an alkyd resin, polyurethane, polyimide, polyethylene, polypropylene, polyvinyl chloride, polystyrene, polyvinyl acetate, Teflon (registered trademark), an ABS resin, an AS resin, an acrylic resin, polyamide, polyacetal, polycarbonate, polyphenylene ether, polybutylene terephthalate, polyethylene terephthalate, cyclic polyolefin, polyphenylene sulfide, polysulfone, polyether sulfone, polyarylate, polyether ether ketone or polyamideimide, or a natural resin, for example, rosin or a natural rubber can be preferably used.

The protective layer 80 may contain the compound capable of being incorporated into the temporary adhesive, if desired, as long as the effects of the invention are not impaired.

The surface 160a (surface of the protective layer 80 opposite to the silicon substrate 61) of the device wafer with a protective layer 160 is pressed against the adhesive layer 11 of the adhesive support 100. Thus, the surface 160a of the device wafer with a protective layer 160 and the adhesive layer 11 are adhered, whereby the adhesive support 100 and the device wafer with a protective layer 160 are temporarily adhered.

Then, the thickness of the silicon substrate 61 is reduced in the same manner as described above (for example, to from a silicon substrate 61′ having a thickness of 1 to 200 μm), thereby obtaining a thin device wafer with a protective layer 160′ as shown in FIG. 3B.

Then, the surface 160a of the thin device wafer with a protective layer 160′ is released from the adhesive layer 11 of the adhesive support 100 in the same manner as described above, thereby obtaining the thin device wafer with a protective layer 160′ as shown in FIG. 3C.

Next, the protective layer 80 of the thin device wafer with a protective layer 160′ is removed from the silicon substrate 61′ and the device chip 62, thereby obtaining a thin device wafer having the device chip 62 provided on the silicon substrate 61′ as shown in FIG. 3D.

For the removal of the protective layer 80, any known methods can be adopted. For example, (1) a method of dissolving and removing the protective layer 80 with a solvent, (2) a method of adhering a peeling tape to the protective layer 80 and peeling mechanically the protective layer 80 from the silicon substrate 61′ and the device chips 62, and (3) a method of decomposing the protective layer 80 or increasing releasing property of the protective layer 80 by performing exposure to light, for example, an ultraviolet ray or an infrared ray, or laser irradiation are exemplified.

The methods (1) and (3) have an advantage in that the removal of the protective layer 80 is easy because the function in these methods extends to the entire surface of the protective layer.

The method (2) has an advantage in that it can be performed at room temperature without requiring a particular device.

The embodiment using the device wafer with a protective layer 160 in place of the device wafer 60 as the member to be processed is effective in the case where TV (total thickness variation) of the thin device wafer obtained by thinning of the device wafer 60 temporary adhered by the adhesive support 100 is intended to be more reduced (that is, in the case where the flatness of the thin device wafer is intended to be more increased).

Specifically, in the case where the device wafer 60 temporary adhered by the adhesive support 100 is thinned, as shown in FIG. 4A, an irregular shape on the device wafer 60 based on a plurality of the device chips 62 is apt to be transferred to the rear surface 61b′ of the thin device wafer 60′ to may become an element for increasing the TTV.

On the other hand, in the case where the device wafer with a protective layer 160 temporary adhered by the adhesive support 100 is thinned, as shown in FIG. 4B, first, it is possible to almost eliminate the irregular shape on the contact surface of the device wafer with a protective layer 160 with the adhesive support 100 because the plurality of the device chips 62 are protected by the protective layer. Thus, even when such a device wafer with a protective layer 160 is subjected to the thinning in the state of being supported by the adhesive support 100, the fear that the shape derived from the plurality of the device chips 62 is transferred to the rear surface 61b″ of the thin device wafer 160′ is reduced and as a result, the TTV of the thin device wafer finally obtained can be more reduced.

Further, in the case where the temporary adhesive according to the invention contains the heat radical polymerization initiator, as the radical polymerization initiator (C), the adhesive layer 11 can be made as an adhesive layer in which the adhesion property decreases by the irradiation of heat. In this case, specifically, the adhesive layer can be made as a layer which has an adhesive property before being subjected to the irradiation of heat and in which the adhesion property is decreased or lost in the region to which heat is irradiated.

Moreover, in the case where the temporary adhesive according to the invention contains the photo-radical polymerization initiator, as the radical polymerization initiator (C), the adhesive layer 11 can be made as an adhesive layer in which the adhesion property decreases by the irradiation of active light or radiation. In this case, specifically, the adhesive layer can be made as a layer which has an adhesive property before being subjected to the irradiation of active light or radiation and in which the adhesion property is decreased or lost in the region to which active light or radiation is irradiated.

Therefore, according to the invention, before adhering the adhesive support 100 to the device wafer 60, active light or radiation, or heat may be irradiated to a surface of the adhesive surface 11 of the adhesive support 100, which is to be adhered to the device wafer 60.

For example, the adhesive layer is converted to an adhesive layer in which a low adhesive region and a high adhesive region are formed by the irradiation of active light or radiation, or heat, and then temporary adhesion of the adhesive support to the member to be processed may be performed. This embodiment described below.

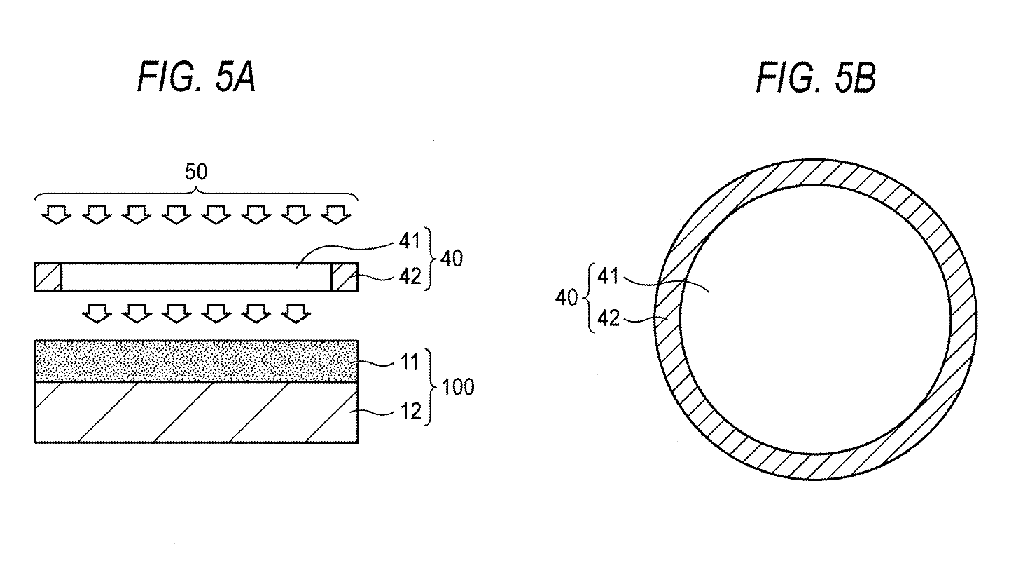

FIG. 5A shows a schematic cross-sectional view illustrating exposure of the adhesive support, and FIG. 5B shows a schematic top view of a mask.

First, the adhesive layer 11 of the adhesive support 100 is irradiated by active light or radiation 50 (that is, exposed) through a mask 40.

As shown in FIG. 5A and FIG. 5B, the mask 40 is composed of a light-transmitting region 41 provided in the central area and a light-shielding region 42 provided in the peripheral area.

Thus, the exposure described above is a pattern exposure in which the central area of the adhesive layer 11 is exposed, but the peripheral area surrounding the central area is not exposed.

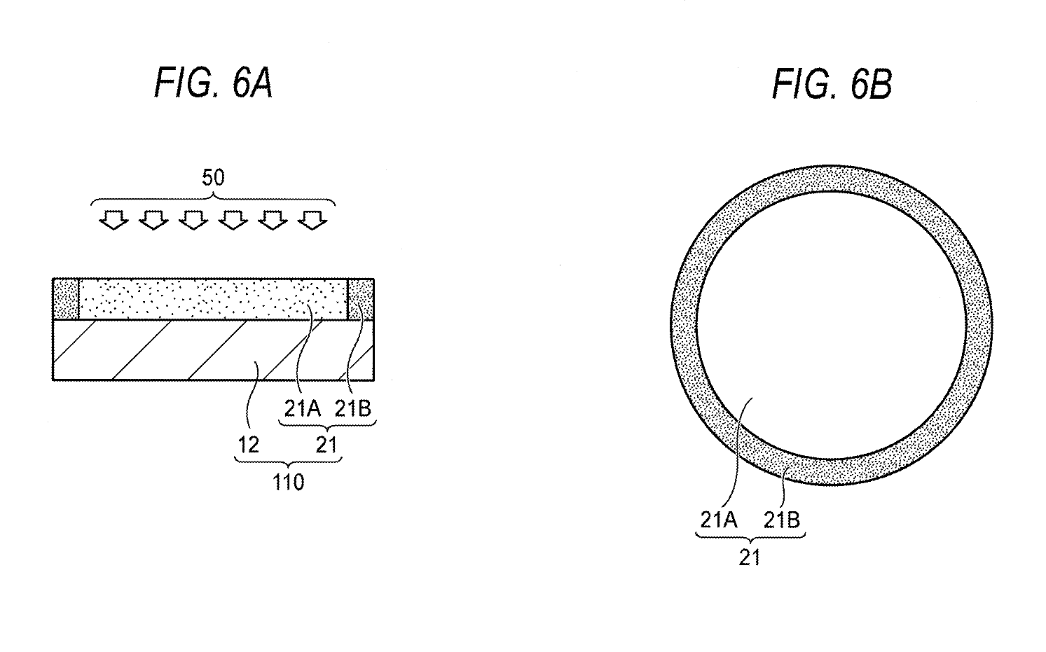

FIG. 6A shows a schematic cross-sectional view of the adhesive support subjected to pattern exposure, and FIG. 6B shows a schematic top view of the adhesive support subjected to pattern exposure.

As described above, in the case where the adhesive layer 11 is an adhesive layer in which the adhesion property decreases by the irradiation of active light or radiation, the adhesive support 100 is converted to an adhesive support 110 having an adhesive layer 21 in which a low adhesive region 21A and a high adhesive region 21B are formed in the central area and the peripheral area, respectively, as shown in FIG. 6A and FIG. 6B.

In the specification, the term “low adhesive region” means a region having a low adhesion property in comparison with the “high adhesive region” and includes a region having no adhesion property (specifically, a “non-adhesive region”). Similarly, the term “high adhesive region” means a region having a high adhesion property in comparison with the “low adhesive region”.

In the adhesive support 110, the low adhesive region 21A and the high adhesive region 21B are provided by the pattern exposure using the mask 40, the respective areas and shapes of the light-transmitting region and the light-shielding region in the mask 40 can be controlled in an order of micron to nanometer. Thus, since the respective areas and shapes of the high adhesive region 21B and the low adhesive region 21A formed in the adhesive layer 21 of the adhesive support 110 can be finely controlled by the pattern exposure, the adhesion property of the adhesive layer as a whole can be controlled in a high accuracy and easily to an adhesive property in such a degree that not only the silicon substrate 61 of the device wafer 60 is temporarily supported more firmly and easily but also the temporary support for the silicon substrate of the thin display wafer 60′ is more easily released without imparting damage to the thin display wafer 60′.

Also, in the high adhesive region 21B and the low adhesive region 21A in the adhesive support 110, the surface properties thereof are differentiated by the pattern exposure, but they are integrated as a structure. Therefore, there is no large difference in the mechanical properties between the high adhesive region 21B and the low adhesive region 21A, and even when the surface 61a of the silicon substrate 61 of the device wafer 60 is adhered to the adhesive layer 21 of the adhesive support 110, and then the rear surface 61b of the silicon substrate 61 is subjected to the thinning processing or the processing for forming a through-silicon electrode, a difference in the pressure relating to the processing (for example, grinding pressure or polishing pressure) hardly arises between the region of the back surface 61b corresponding to the high adhesive region 21B of the adhesive layer 21 and the region of the back surface 61b corresponding to the low adhesive region 21 A, and the influence of the high adhesive region 21B and the low adhesive region 21A on the processing accuracy in the processing described above is small. This is particularly effective in the case of obtaining a thin device wafer 60′ having a thickness, for example, from 1 to 200 μm, which is likely to cause the problem described above.

Therefore, the embodiment using the adhesive support 110 is preferred as an embodiment wherein the silicon substrate 61 can be temporarily supported more firmly and easily while suppressing the influence on the processing accuracy when the silicon substrate 61 of the device wafer 60 is subjected to the processing described above and the temporary support for the thin display wafer 60′ can be more easily released without imparting damage to the thin display wafer 60′.

Also, the adhesive layer 11 is converted to an adhesive layer in which the adhesion property decreases towards the outer surface from the inner surface on the substrate side by the irradiation of active light or radiation, or heat, and then temporary adhesion of the adhesive support to the member to be processed may be performed. This embodiment described below.

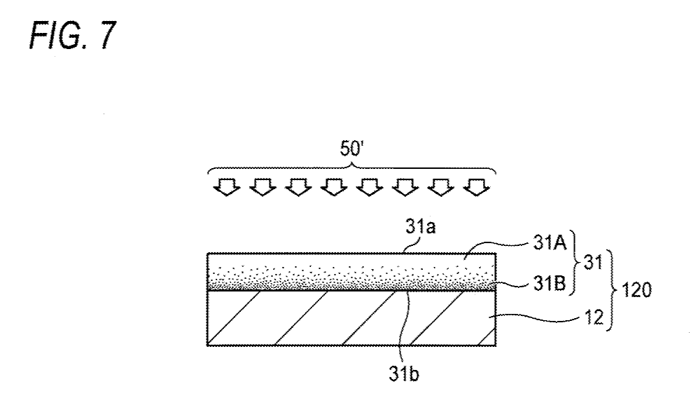

FIG. 7 is a schematic cross-sectional view illustrating irradiation of active light or radiation, or heat to the adhesive support.

First, active light or radiation, or heat 50′ is irradiated to the outer surface of the adhesive layer 11, whereby the adhesive support 100 is converted into an adhesive support 120 having an adhesive layer 31 in which the adhesion property is decreased toward the outer surface 31a from the inner surface 31b on the substrate side, as shown in FIG. 7.

Specifically, the adhesive layer 31 comes to have a low adhesive region 31A and a high adhesive region 31B on the outer surface 31a side and the inner surface 31b side, respectively.

Such an adhesive layer 31 can be easily formed by controlling the irradiation dose of the active light or radiation, or heat 50′ to such an irradiation dose that the active light or radiation, or heat 50′ sufficiently irradiates the outer surface 31a, but the active light or radiation, or heat 50′ does not reach to the inner surface 31b.

The change in the irradiation dose as described above can be easily performed by changing the setting of an exposure machine or a heating device so that not only the cost of equipment can be reduced but also formation of the adhesive layer 21 or 31 can be performed without spending a long time.

Also, in the embodiment according to the invention described above, the adhesive layer 31 which is integral as a structure but is positively caused to have lower adhesion property on the outer surface 31a than the adhesion property on the inner surface 31b is formed by combining the adhesive layer 11 and the irradiation method and therefore, another layer, for example, a separating layer need not be provided.

As described above, the formation of the adhesive layer 31 is easy.

Further, each of the adhesion property on the outer surface 31a and the adhesion property on the inner surface 31b can be controlled with good precision, for example, by selecting the material constituting the adhesive layer 11 and adjusting the irradiation dose of the active light, radiation or heat.

As a result, the adhesion property of the adhesive layer 31 to each of the substrate 12 and the silicon substrate 61 can be easily controlled with high precision to such a degree of adhesion property that not only the silicon substrate 61 of the device wafer 60 can be temporarily supported firmly and easily but also the temporary support for the silicon substrate of the thin device wafer 60′ can be easily released without imparting damage to the thin device wafer 60′.

Therefore, the embodiment using the adhesive support 120 is also preferred as an embodiment wherein not only the silicon substrate 61 can be temporarily supported more firmly and easily when the silicon substrate 61 of the device wafer 60 is subjected to the processing described above but also the temporary support for the thin display wafer 60′ can be more easily released without imparting damage to the thin display wafer 60′.

The production method of semiconductor device according to the invention is not limited to the embodiments described above, and appropriate modifications, improvements and the like can be made therein.

In the embodiments described above, the adhesive layer formed from the temporary adhesive for production of semiconductor device according to the invention is provided on the carrier substrate to constitute the adhesive support before the temporary adhesion of a device wafer, but the adhesive layer may be formed on a member to be processed, for example, a device wafer and then the member to be processed having the adhesive layer provided thereon may be temporary adhered to the substrate.

Also, for example, a mask used for the pattern exposure may be a binary mask or a halftone mask.

Also, the exposure is mask exposure through a mask, but may be selective exposure by drawing using also an electron beam or the like.

In the embodiments described above, the adhesive layer has a single-layer structure, but the adhesive layer may have a multilayer structure. Examples of the method for forming an adhesive layer having a multilayer structure include a method of stepwise coating an adhesive composition by the conventionally known method described above before irradiation of active light or radiation, and a method of coating an adhesive composition by the conventionally known method described above after irradiation of active light or radiation. In the embodiment where the adhesive layer has a multilayer structure, for example, in the case where the adhesive layer 11 is an adhesive layer in which the adhesion property decreases by the irradiation of active light or radiation, or heat, the adhesion property as an entire adhesive layer can also be decreased by decreasing the adhesion property between respective layers by the irradiation of active light or radiation, or heat.

In the embodiments described above, the member to be processed which is supported by the adhesive support is a silicon substrate, but the member to be processed is not limited thereto and may be any member to be processed which can be subjected to a mechanical or chemical processing in the production method of semiconductor device.

For example, the member to be processed includes a compound semiconductor substrate, and specific examples of the compound semiconductor substrate include an SiC substrate, an SiGe substrate, a ZnS substrate, a ZnSe substrate, a GaAs substrate, an InP substrate and a GaN substrate.

Further, in the embodiments described above, the mechanical or chemical processing applied to the silicon substrate which is supported by the adhesive support is the thinning processing of the silicon substrate or the processing for forming a through-silicon electrode, but the mechanical or chemical processing is not limited thereto and may be any processing required in the production method of semiconductor device.

In addition, the light-transmitting region and the light-shielding region in the mask, the high adhesive region and the low adhesive region in the adhesive layer, and the shape, dimension, number, arrangement portion and the like of device chip in the device wafer, which are exemplified in the embodiments described above, are arbitrary and not limited as long as the invention can be achieved.

The invention also relates to a kit comprising a compound for protective layer and the temporary adhesive for production of semiconductor device according to the invention described above.

The invention also relates to a kit comprising a compound for protective layer, a release solution and the temporary adhesive for production of semiconductor device according to the invention described above.

Specific examples and preferred examples of the compound for protective layer and the release solution are same as those described above.

### EXAMPLE

The invention will be described more specifically with reference to the examples, but the invention should not be construed as being limited thereto as long as the gist of the invention is not deviated. All “part” and “%” therein are weigh basis unless otherwise specified.

### <Formation of Adhesive Support>

Each liquid adhesive composition (temporary adhesive) having the composition shown in Table 1 below was coated on a 4-inch Si wafer by a spin coater (Opticoat MS-A100 produced by Mikasa Co., Ltd., 1,200 rpm, 30 seconds) and then baked at 100° C. for 30 seconds to form Wafer 1 having provided thereon an adhesive layer having a thickness of 3 μm (that is, an adhesive support).

TABLE 1

| | Specific | | Polymer | | Radical Polymerization | | | | | |
|---|---|---|---|---|---|---|---|---|---|---|
| | Monomer (A) | | Compound (B) | | Initiator (C) | | Other Monomer (D) | | Solvent | |
| | | Parts by | | Parts by | | Parts by | | Parts by | | Parts by |
| | Kind | Weight | Kind | Weight | Kind | Weight | Kind | Weight | Kind | Weight |
| Liquid Adhesive | (1) | 1 | Polymer | 10 | Photo-radical | 2 | Polymerizable | 30 | Solvent | 57 |
| Composition (1) | | | Compound (1) | | Polymerization | | Monomer (1) | | (1) | |
| | | | | | Initiator (1) | | | | | |
| Liquid Adhesive | (2) | 1 | Polymer | 10 | Photo-radical | 2 | Polymerizable | 30 | Solvent | 57 |
| Composition (2) | | | Compound (1) | | Polymerization | | Monomer (1) | | (1) | |
| | | | | | Initiator (1) | | | | | |
| Liquid Adhesive | (3) | 3 | Polymer | 10 | Photo-radical | 2 | Polymerizable | 30 | Solvent | 55 |
| Composition (3) | | | Compound (1) | | Polymerization | | Monomer (1) | | (1) | |
| | | | | | Initiator (1) | | | | | |
| Liquid Adhesive | (4) | 3 | Polymer | 10 | Photo-radical | 2 | Polymerizable | 30 | Solvent | 55 |
| Composition (4) | | | Compound (1) | | Polymerization | | Monomer (1) | | (1) | |
| | | | | | Initiator (1) | | | | | |
| Liquid Adhesive | (5) | 3 | Polymer | 10 | Photo-radical | 2 | Polymerizable | 30 | Solvent | 55 |
| Composition (5) | | | Compound (1) | | Polymerization | | Monomer (1) | | (1) | |
| | | | | | Initiator (1) | | | | | |
| Liquid Adhesive | (6) | 1 | Polymer | 10 | Photo-radical | 2 | Polymerizable | 30 | Solvent | 57 |
| Composition (6) | | | Compound (1) | | Polymerization | | Monomer (1) | | (1) | |
| | | | | | Initiator (1) | | | | | |
| Liquid Adhesive | (7) | 1 | Polymer | 10 | Photo-radical | 2 | Polymerizable | 30 | Solvent | 57 |
| Composition (7) | | | Compound (1) | | Polymerization | | Monomer (1) | | (1) | |
| | | | | | Initiator (1) | | | | | |
| Liquid Adhesive | (1) | 0.1 | Polymer | 9.1 | Photo-radical | 2 | Polymerizable | 30.9 | Solvent | 57.9 |
| Composition (8) | | | Compound (1) | | Polymerization | | Monomer (1) | | (1) | |
| | | | | | Initiator (1) | | | | | |
| Liquid Adhesive | (1) | 5 | Polymer | 14 | Photo-radical | 2 | Polymerizable | 26 | Solvent | 53 |
| Composition (9) | | | Compound (1) | | Polymerization | | Monomer (1) | | (1) | |
| | | | | | Initiator (1) | | | | | |
| Liquid Adhesive | (1) | 10 | Polymer | 19 | Photo-radical | 2 | Polymerizable | 21 | Solvent | 48 |
| Composition (10) | | | Compound (1) | | Polymerization | | Monomer (1) | | (1) | |
| | | | | | Initiator (1) | | | | | |
| Liquid Adhesive | (6) | 0.1 | Polymer | 9.1 | Photo-radical | 2 | Polymerizable | 30.9 | Solvent | 57.9 |
| Composition (11) | | | Compound (1) | | Polymerization | | Monomer (1) | | (1) | |
| | | | | | Initiator (1) | | | | | |
| Liquid Adhesive | (6) | 5 | Polymer | 14 | Photo-radical | 2 | Polymerizable | 26 | Solvent | 53 |
| Composition (12) | | | Compound (1) | | Polymerization | | Monomer (1) | | (1) | |
| | | | | | Initiator (1) | | | | | |
| Liquid Adhesive | (6) | 10 | Polymer | 19 | Photo-radical | 2 | Polymerizable | 21 | Solvent | 48 |
| Composition (13) | | | Compound (1) | | Polymerization | | Monomer (1) | | (1) | |
| | | | | | Initiator (1) | | | | | |
| Liquid Adhesive | (1) | 1 | Polymer | 10 | Photo-radical | 2 | Polymerizable | 30 | Solvent | 57 |
| Composition (14) | | | Compound (1) | | Polymerization | | Monomer (2) | | (1) | |
| | | | | | Initiator (1) | | | | | |
| Liquid Adhesive | (1) | 1 | Polymer | 10 | Photo-radical | 2 | Polymerizable | 30 | Solvent | 57 |
| Composition (15) | | | Compound (1) | | Polymerization | | Monomer (3) | | (1) | |
| | | | | | Initiator (1) | | | | | |
| Liquid Adhesive | (1 ) | 1 | Polymer | 10 | Photo-radical | 2 | Polymerizable | 30 | Solvent | 57 |
| Composition (16) | | | Compound (1) | | Polymerization | | Monomer (2) | | (1) | |
| | | | | | Initiator (2) | | | | | |
| Liquid Adhesive | (1) | 1 | Polymer | 10 | Photo-radical | 2 | Polymerizable | 30 | Solvent | 56.5 |
| Composition (17) | | | Compound (1) | | Polymerization | | Monomer (2) | | (1) | |
| | | | | | Initiator (1) | | | | | |
| | | | | | Heat Radical | 0.5 | | | | |
| | | | | | Polymerization | | | | | |
| | | | | | Initiator (1) | | | | | |
| Liquid Adhesive | (1) | 1 | Polymer | 10 | Photo-radical | 2 | Polymerizable | 30 | Solvent | 57 |
| Composition (18) | | | Compound (2) | | Polymerization | | Monomer (2) | | (1) | |
| | | | | | Initiator (1) | | | | | |
| Liquid Adhesive | (1) | 20 | Polymer | 20 | Photo-radical | 2 | — | 0 | Solvent | 75 |
| Composition (19) | | | Compound (1) | | Polymerization | | | | (1) | |
| | | | | | Initiator (1) | | | | | |
| Liquid Adhesive | (8) | 1 | Polymer | 10 | Photo-radical | 2 | Polymerizable | 30 | Solvent | 57 |
| Composition (20) | | | Compound (1) | | Polymerization | | Monomer (1) | | (1) | |
| | | | | | Initiator (1) | | | | | |
| Liquid Adhesive | (9) | 1 | Polymer | 10 | Photo-radical | 2 | Polymerizable | 30 | Solvent | 57 |
| Composition (21) | | | Compound (1) | | Polymerization | | Monomer (1) | | (1) | |
| | | | | | Initiator (1) | | | | | |
| Liquid Adhesive | (10) | 1 | Polymer | 10 | Photo-radical | 2 | Polymerizable | 30 | Solvent | 57 |
| Composition (22) | | | Compound (1) | | Polymerization | | Monomer (1) | | (1) | |
| | | | | | Initiator (1) | | | | | |
| Liquid Adhesive | — | 0 | Polymer | 9 | Photo-radical | 2 | Polymerizable | 31 | Solvent | 58 |
| Composition (1) | | | Compound (1) | | Polymerization | | Monomer (1) | | (1) | |
| for Comparative | | | | | Initiator (1) | | | | | |
| Example | | | | | | | | | | |
| Liquid Adhesive | (1) | 1 | Polymer | 10 | — | 0 | Polymerizable | 30 | Solvent | 59 |
| Composition (2) | | | Compound (1) | | | | Monomer (1) | | (1) | |
| for Comparative | | | | | | | | | | |
| Example | | | | | | | | | | |
| Liquid Adhesive | (1) | 1 | — | 0 | Photo-radical | 2 | Polymerizable | 30 | Solvent | 67 |
| Composition (3) | | | | | Polymerization | | Monomer (1) | | (1) | |
| for Comparative | | | | | Initiator (1) | | | | | |
| Example | | | | | | | | | | |

### [(A) Radical Polymerizable Monomer or Oligomer Containing Fluorine Atom or Silicon Atom]

### Specific Monomer or Oligomer (1):

2-(Perfluorohexyl)ethyl acrylate [F(CF₂)₆CH₂CH₂OCOCH═CH₂, Monofunctional monomer]

### Specific Monomer or Oligomer (2):

2-(Perfluorobutyl)ethyl methacrylate [F(CF₂)₄CH₂CH₂OCOC(CH₃)═CH₂. Monofunctional monomer]

### Specific Monomer or Oligomer (Fluorine-Based) (3):

RS-76-E (produced by DIC Corp.)

### Specific Monomer or Oligomer (Fluorine-Based) (4):

RS-72-K (produced by DIC Corp.)

### Specific Monomer or Oligomer (Fluorine-Based) (5):

OPTOOL DAC-HP (produced by Daikin Industries, Ltd.)

### Specific Monomer or Oligomer (Silicon-Based) (6):

X-22-164 (produced by Shin-Etsu Chemical Co., Ltd., Difunctional monomer)

### Specific Monomer or Oligomer (Silicon-Based) (7):

X-22-164E (produced by Shin-Etsu Chemical Co., Ltd., Difunctional monomer)

### Specific Monomer or Oligomer (Fluorine-Based) (8):

Difunctional monomer shown below

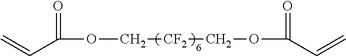

### Specific Monomer or Oligomer (Fluorine-Based) (9):

Difunctional monomer shown below

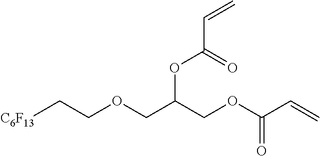

### Specific Monomer or Oligomer (Silicon-Based) (10):

X-22-2426 (produced by Shin-Etsu Chemical Co., Ltd., Monofunctional monomer)

### [(B) Polymer Compound]

### Polymer Compound (1):

ESTYRENE MS200NT (styrene-methyl methacrylate copolymer produced by Nippon Steel Chemical Co., Ltd.)

### Polymer Compound (2):

Polymethyl methacrylate produced by Sigma-Aldrich Co., Mw: 120,000)

### [(C) Radical Polymerization Initiator]

### Photo-Radical Polymerization Initiator (1):

IRGACURE OXE 02 (produced by BASF Corp.)

### Photo-Radical Polymerization Initiator (2):

KAYACURE DETX (produced by Nippon Kayaku Co., Ltd.)

### Heat Radical Polymerization Initiator (1):

PERBUTYL Z (tert-butyl peroxybenzoate produced by NOF Corp., decomposition temperature (10 hour half-life temperature=104° C.))

### [(D) Other Polymerizable Monomer]

### Polymerizable Monomer (1):

UA-1100H (tetrafunctional urethane acrylate, produced by Shin-Nakamura Chemical Co., Ltd.)

### Polymerizable Monomer (2):

A-TMPT (trimethylolpropane triacrylate, produced by Shin-Nakamura Chemical Co., Ltd.)

### Polymerizable Monomer (3):

A-DPH (hexafunctional acrylate, produced by Shin-Nakamura Chemical Co., Ltd.)

### [Solvent]

### Solvent (1):

1-Methoxy-2-propanol acetate

### <Preparation of Member to be Processed>

As a member to be processed having no protective layer, a 4-inch Si wafer was used as it was.

As a member to be processed having a protective layer, a 20% by weight p-menthane solution of compound for protective layer shown below was coated on a 4-inch Si wafer by a spin coater (Opticoat MS-A100 produced by Mikasa Co., Ltd., 1,200 rpm, 30 seconds) and then baked at 100° C. for 300 seconds to form a wafer having provided thereon a protective layer having a thickness of 20 μm.

In spite of the presence or absence of the protective layer, the wafer described above as the member to be processed is referred collectively to as Wafer 2.

### [Compound for Protective Layer]

Compound for Protective Layer (1):

TOPAS 5013 (produced by Polyplastics Co., Ltd.)

### <Preparation of Adhesion Property Test Piece>

Using the temporary adhesive composed of each liquid adhesive composition as shown in Table 2 below, each process of “exposure” and “bonding with pressure” were conducted in this order to prepare an adhesion property test piece.

### [Exposure]

From the adhesive layer side of Wafer 1, a central portion of the adhesive layer excluding an outer peripheral portion of 3 mm was exposed through a mask protecting (shielding) the outer peripheral portion of 5 mm of the adhesive layer using an UV exposure device (LC8 produced by Hamamatsu Photonics K.K.) with light having a wavelength of 254 nm at an exposure dose of 2,000 mJ/cm².

[Bonding with Pressure]

Wafer 2 was superimposed on the adhesive layer of Wafer 1 and adhered under pressure of 20N/cm² at 200° C. for 300 seconds. In the case where Wafer 2 was the 4-inch Si wafer provided with the protective layer, the protective layer was superimposed on the adhesive layer of Wafer 1 and adhered under pressure as described above.

### <Adhesive Force Measurement of Adhesion Property Test Piece at High Temperature>

As to the shear adhesive force of the adhesion property test piece prepared under the conditions described in Table 2, tensile measurement was performed in the direction along the surface of the adhesive layer under the condition of 250 mm/min while heating at 100° C. using a tensile tester (Digital Force Gauge Model ZP-50N produced by Imada Co., Ltd.). The results are shown in Table 2 below.

### <Releasing Property>

The test piece prepared under the conditions described in Table 2 was immersed in the release solution described in Table 2 at 25° C. for 10 minutes. The test piece was taken from the release solution, washed carefully with pure water, and dried at 25° C. The test piece was pulled in the direction perpendicular to the adhesive layer, and the case where the Si wafer could be peeled with a very small force without imparting damage to the Si wafer was ranked as “A”, the case where the Si wafer could be peeled with a small force without imparting damage to the Si wafer was ranked as “B”, the case where the Si wafer could be peeled with a strong force without imparting damage to the Si wafer was ranked as “C”, and the case where the Si wafer could not be peeled was ranked as “D”. The occurrence of the damage of the Si wafer was visually confirmed.

<Releasing Property after High Temperature Process>

The test piece prepared under the conditions described in Table 2 was subjected to heating at 250° C. for 30 minutes, cooled to room temperature, and immersed in the release solution described in Table 2 at 25° C. for 10 minutes. The test piece was taken from the release solution, washed carefully with pure water, and dried at 25° C. The test piece was pulled in the direction perpendicular to the adhesive layer, and the case where the Si wafer could be peeled with a very small force without imparting damage to the Si wafer was ranked as “A”, the case where the Si wafer could be peeled with a small force without imparting damage to the Si wafer was ranked as “B”, the case where the Si wafer could be peeled with a strong force without imparting damage to the Si wafer was ranked as “C”, and the case where the Si wafer could not be peeled was ranked as “D”. The occurrence of the damage of the Si wafer was visually confirmed.

TABLE 2

| | | Protective | | | | | |
|---|---|---|---|---|---|---|---|
| | | Layer of | | | | | |
| | | Member to be | Result of | | | | |
| | | Processed | Adhesive | | | | |
| | | (Number indicates | Force | | | | |
| | | number of | Measurement | | | Releasing Property | |
| | | compound for | Adhesion | | | after Heating | |
| | Liquid Adhesive | protective layer | Property | Releasing Property | | Process at 250° C. | |
| | Composition | used) | (N/25 mm²) | Release Solution | Result | Release Solution | Result |
| Example 1 | (1) | None | 40 | 2-Heptanone | B | 2-Heptanone | B |
| Example 2 | (2) | None | 40 | 2-Heptanone | B | 2-Heptanone | B |
| Example 3 | (3) | None | 40 | 2-Heptanone | B | 2-Heptanone | B |
| Example 4 | (4) | None | 40 | 2-Heptanone | B | 2-Heptanone | B |
| Example 5 | (5) | None | 40 | 2-Heptanone | B | 2-Heptanone | B |
| Example 6 | (6) | None | 40 | 2-Heptanone | C | 2-Heptanone | C |
| Example 7 | (7) | None | 40 | 2-Heptanone | C | 2-Heptanone | C |
| Example 8 | (8) | None | 42 | 2-Heptanone | B | 2-Heptanone | B |
| Example 9 | (9) | None | 38 | 2-Heptanone | B | 2-Heptanone | B |
| Example 10 | (10) | None | 30 | 2-Heptanone | C | 2-Heptanone | C |
| Example 11 | (11) | None | 42 | 2-Heptanone | B | 2-Heptanone | B |
| Example 12 | (12) | None | 38 | 2-Heptanone | B | 2-Heptanone | B |
| Example 13 | (13) | None | 30 | 2-Heptanone | C | 2-Heptanone | C |
| Example 14 | (14) | None | 40 | 2-Heptanone | B | 2-Heptanone | B |
| Example 15 | (15) | None | 40 | 2-Heptanone | B | 2-Heptanone | B |
| Example 16 | (16) | None | 40 | 2-Heptanone | B | 2-Heptanone | B |
| Example 17 | (17) | None | 50 | 2-Heptanone | B | 2-Heptanone | B |
| Example 18 | (18) | None | 40 | 2-Heptanone | B | 2-Heptanone | C |
| Example 19 | (19) | None | 30 | 2-Heptanone | B | 2-Heptanone | B |
| Example 20 | (1) | (1) | 40 | Limonene | B | Limonene | A |
| Example 21 | (4) | (1) | 40 | Limonene | A | Limonene | A |
| Example 22 | (6) | (1) | 40 | Limonene | A | Limonene | A |
| Example 23 | (20) | None | 45 | 2-Heptanone | A | 2-Heptanone | B |
| Example 24 | (21) | None | 45 | 2-Heptanone | A | 2-Heptanone | B |
| Example 25 | (22) | None | 35 | 2-Heptanone | C | 2-Heptanone | C |
| Comparative | Liquid Adhesive | None | 40 | 2-Heptanone | C | 2-Heptanone | D |
| Example 1 | Composition (1) | | | | | | |
| | for Comparative | | | | | | |
| | Example | | | | | | |
| Comparative | Liquid Adhesive | (1) | 40 | Limonene | C | Limonene | D |
| Example 2 | Composition (1) | | | | | | |
| | for Comparative | | | | | | |
| | Example | | | | | | |
| Comparative | Liquid Adhesive | None | 35 | 2-Heptanone | C | 2-Heptanone | D |
| Example 3 | Composition (2) | | | | | | |
| | for Comparative | | | | | | |
| | Example | | | | | | |
| Comparative | Liquid Adhesive | None | Due to poor coating property evaluation could not be conducted. | | | | |
| Example 4 | Composition (3) | | | | | | |
| | for Comparative | | | | | | |
| | Example | | | | | | |

As described above, it can be seen that in Comparative Examples 1 and 2 using the temporary adhesive not containing the radical polymerizable monomer or oligomer containing a fluorine atom or a silicon atom (A) and Comparative Example 3 using the temporary adhesive not containing the radical polymerization initiator, the releasing property decreases when subjected to the high temperature process. In Comparative Example 4 using the temporary adhesive not containing the polymer compound (B), the monomer spread in a spot-like state on the surface of wafer after the coating of wafer and thus, the evaluation could not be conducted.

On the other hand, it can be understood that in Examples 1 to 25 using the temporary adhesive according to the invention, the excellent coating property is achieved, and not only the good results are obtained with respect to the adhesion property and the releasing property but also the good result is obtained with respect to the releasing property after being subjected to the high temperature process.

Also, it can be understood that in Example 17 using the temporary adhesive containing the photo-radical polymerization initiator and the heat radical polymerization initiator as the radical polymerization initiator (C), the adhesion property is more excellent.

Thus, the temporary adhesive according to the invention can easily release the temporary support for the member processed without imparting damage to the member processed even after being subjected to the high temperature process when the member to be processed (for example, a semiconductor wafer) is subjected to a mechanical or chemical processing.

Further, the region exposed to light in the adhesive layer formed through the exposure process did not exhibit the adhesion property at all. Since, for example, the adhesive support capable of adhering the member to be processed only by the outer peripheral portion of the adhesive layer thereof can be formed according to the technique, particularly, in the case where the member to be processed is a device wafer, when the adhesive support is released from the device wafer, it is possible to more reduce damage of the inner portion of the device.

### DESCRIPTION OF REFERENCE NUMERALS AND SIGNS

11, 11′, 21, 31: Adhesive layer
12: Carrier substrate
21A, 31A: Low adhesive region
21B, 31B: High adhesive region
40: Mask
41: Light-transmitting region
42: Light-shielding region
50: Active light or radiation
50′: Active light or radiation, or heat
60: Device wafer
60′: Thin device wafer
61,61′: Silicon substrate
62: Device chip
63: Bump
70: Tape
80: Protective layer
100, 100′, 110, 120: Adhesive support
160: Device wafer with a protective layer
160′: Thin device wafer with a protective layer

### INDUSTRIAL APPLICABILITY

According to the invention, a temporary adhesive for production of semiconductor device, which is excellent in coating property, which can temporarily support a member to be processed with a high adhesive force when the member to be processed is subjected to a mechanical or chemical processing, and which can easily release the temporary support for the member processed without imparting damage to the member processed even after being subjected to a process at a high temperature in the production method of semiconductor device, and an adhesive support and a production method of semiconductor device using the same can be provided.

Although the invention has been described in detail and by reference to specific embodiments, it is apparent to those skilled in the art that it is possible to add various alterations and modifications insofar as the alterations and modifications do not deviate from the spirit and the scope of the invention.

1. A temporary adhesive for production of semiconductor device comprising (A) a radical polymerizable monomer or oligomer containing a fluorine atom or a silicon atom, (B) a polymer compound, and (C) a radical polymerization initiator.

2. The temporary adhesive for production of semiconductor device as claimed in claim 1, which further comprises (D) a radical polymerizable monomer or oligomer which is different from the radical polymerizable monomer or oligomer (A).

3. The temporary adhesive for production of semiconductor device as claimed in claim 1, wherein the radical polymerizable monomer or oligomer (A) has two or more radical polymerizable functional groups.

4. The temporary adhesive for production of semiconductor device as claimed in claim 1, wherein the radical polymerizable monomer or oligomer (A) is a radical polymerizable monomer or oligomer containing a fluorine atom.

5. The temporary adhesive for production of semiconductor device as claimed in claim 1, wherein the radical polymerization initiator (C) is a photo-radical polymerization initiator.

6. The temporary adhesive for production of semiconductor device as claimed in claim 1, which comprises as the radical polymerization initiator (C), a photo-radical polymerization initiator and a heat radical polymerization initiator.

7. An adhesive support comprising a substrate and an adhesive layer formed from the temporary adhesive for production of semiconductor device as claimed in claim 1.

8.-12. (canceled)

13. A kit comprising a compound for protective layer, and the temporary adhesive for production of semiconductor device as claimed in claim 1.

14. A kit comprising a compound for protective layer, a release solution, and the temporary adhesive for production of semiconductor device as claimed in claim 1.
